(19) United States
(12) Patent Application Publication
(10) Pub. No.: US 2024/0057462 A1
(43) Pub. Date: Feb. 15, 2024

(54) MANUFACTURING EQUIPMENT OF DISPLAY DEVICE

(71) Applicant: SEMICONDUCTOR ENERGY LABORATORY CO., LTD., Atsugi-shi, Kanagawa-ken (JP)

(72) Inventors: Shingo EGUCHI, Atsugi, Kanagawa (JP); Hiroki ADACHI, Tochigi, Tochigi (JP); Kenichi OKAZAKI, Atsugi, Kanagawa (JP); Yasumasa YAMANE, Atsugi, Kanagawa (JP); Naoto KUSUMOTO, Isehara, Kanagawa (JP); Kensuke YOSHIZUMI, Atsugi, Kanagawa (JP); Shunpei YAMAZAKI, Setagaya, Tokyo (JP)

(21) Appl. No.: 18/258,104

(22) PCT Filed: Dec. 15, 2021
(86) PCT No.: PCT/IB2021/061730

§ 371 Date: Jun. 16, 2023

(30) Foreign Application Priority Data
Dec. 25, 2020 (JP) 2020-216021

(51) Int. Cl. H10K 71/20; H10K 71/16; H01L 21/677; G03F 7/00

(52) U.S. Cl. CPC H10K 71/233; H10K 71/16; H01L 21/67706; G03F 7/0007

(57) ABSTRACT

Manufacturing equipment of a display device that is capable of successively performing steps from formation of a pixel circuit up to formation of a light-emitting element is provided. The manufacturing equipment includes a manufacturing apparatus of a light-emitting device that is capable of successively performing a film formation step, a lithography step, an etching step, and a sealing step for formation of an organic EL element and a manufacturing apparatus for formation of a pixel circuit that drives the organic EL element. Formation from the pixel circuit up to the organic EL element can be performed successively, so that a display device with a high yield and high reliability can be formed.

### TECHNICAL FIELD

One embodiment of the present invention relates to manufacturing equipment and a manufacturing method of a display device.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting device, a lighting device, a power storage device, a memory device, an imaging device, an operation method thereof, and a manufacturing method thereof.

### BACKGROUND ART

In recent years, higher-resolution display panels have been required. Examples of devices that require high-resolution display panels include a smartphone, a tablet terminal, and a laptop computer. Furthermore, higher resolution has been required for stationary display devices such as a television device and a monitor device along with an increase in definition. Examples of devices required to have the highest resolution include devices for virtual reality (VR) and augmented reality (AR).

Typical examples of display devices that can be used in display panels include a liquid crystal display device, alight-emitting device including alight-emitting element such as an organic EL (Electro Luminescence) element or a light-emitting diode (LED), and electronic paper performing display by an electrophoretic method or the like.

The organic EL element has a structure in which a layer containing a light-emitting organic compound is provided between a pair of electrodes. By applying a voltage to this element, light emission can be obtained from the light-emitting organic compound. A display device including such an organic EL element does not need a backlight that is necessary for a liquid crystal display device and the like, and thus can be a thin, lightweight, high-contrast, and low-power display device. Patent Document 1, for example, discloses an example of a display device that includes an organic EL element.

### REFERENCE

### Patent Document

[Patent Document 1] Japanese Published Patent Application No. 2002-324673

### SUMMARY OF THE INVENTION

### Problems to be Solved by the Invention

As an organic EL display device capable of full-color display, a structure in which a white light-emitting element and color filters are combined and a structure in which R, G, and B light-emitting elements are formed on the same plane are known.

The latter structure is optimal in terms of power consumption, and light-emitting materials are separately deposited using a metal mask or the like in manufacture of medium- and small-size panels under the existing circumstances. However, the process using a metal mask has low alignment accuracy and accordingly requires a reduction in the area occupied by a light-emitting element in a pixel, resulting in difficulty in increasing an aperture ratio.

Therefore, an object of the process using a metal mask is to increase the density of pixels or emission intensity. In order to increase the aperture ratio, the area of the light-emitting element is preferably increased with the use of a lithography step or the like. However, the reliability of a material included in the light-emitting element is impaired when impurities (e.g., water, oxygen, and hydrogen) in the air enter the material, necessitating performing a plurality of steps in a region whose atmosphere is controlled.

Small and high-resolution displays are demanded for AR and VR applications. Displays for AR and VR applications are incorporated into devices with small volume, such as eyeglass-type or goggle-type devices, and accordingly preferably have narrow bezels. Therefore, drivers for a pixel circuit and the like are preferably provided below the pixel circuit. Furthermore, to manufacture these small displays, manufacturing equipment capable of successively performing steps from a pixel circuit up to a light-emitting element is desired.

In view of the above, an object of one embodiment of the present invention is to provide manufacturing equipment of a display device that is capable of successively performing steps from formation of a pixel circuit up to formation of a light-emitting element without exposure to the air. Another object is to provide manufacturing equipment of a display device that is capable of forming a light-emitting element without using a metal mask. Another object is to provide a manufacturing method of a display device.

Note that the description of these objects does not preclude the existence of other objects. One embodiment of the present invention does not need to achieve all these objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to manufacturing equipment of a light-emitting device.

One embodiment of the present invention is manufacturing equipment of a display device. The manufacturing equipment includes a manufacturing apparatus of a pixel circuit and a manufacturing apparatus of a light-emitting device. The manufacturing apparatus of the light-emitting device includes a first load lock chamber, a first cluster, and a second cluster; the first load lock chamber is connected to the first cluster through a first gate valve; the first load lock chamber is connected to the second cluster through a second gate valve; the pressure in the first load lock chamber is controlled to be reduced pressure or the atmosphere therein is controlled to be an inert gas atmosphere; the pressure in the first cluster is controlled to be reduced pressure; the atmosphere in the second cluster is controlled to be an inert gas atmosphere; the first cluster includes a first delivery device, a plurality of film formation apparatuses, and an etching apparatus; the second cluster includes a second delivery device and a plurality of apparatuses performing a lithography step; the manufacturing apparatus of the pixel circuit includes a second load lock chamber; the first load lock chamber is connected to the second load lock chamber through a transfer chamber; and the manufacturing equipment has a function of forming an island-shaped light-emitting device including an organic compound over a pixel electrode formed over a substrate in the manufacturing apparatus of the pixel circuit.

The film formation apparatus is preferably one or more selected from an evaporation apparatus, a sputtering apparatus, a CVD apparatus, and an ALD apparatus, and the etching apparatus is preferably a dry etching apparatus.

The first cluster preferably includes a vacuum baking apparatus.

As the plurality of apparatuses performing the lithography step, an application apparatus, a light-exposure apparatus, a development apparatus, and a baking apparatus can be included. Alternatively, as the plurality of apparatuses performing the lithography step, an application device and a nanoimprint apparatus can be included.

In the first cluster, the substrate attached to a substrate delivery jig can be subjected to treatment. The substrate delivery jig can include a first jig and a second jig, and the substrate can be held between the first jig and the second jig.

Alternatively, the substrate delivery jig can include a first jig and a plurality of second jigs, a plurality of substrates can be placed apart from each other over the first jig, and the substrates can be held between the first jig and the second jigs.

The first cluster can include a device detaching the substrate transfer jig.

The first cluster can include a device reversing the substrate to which the substrate delivery jig is attached.

The manufacturing apparatus of the pixel circuit includes a third cluster and a fourth cluster; the second load lock chamber is connected to the third cluster through a third gate valve; the second load lock chamber is connected to the fourth cluster through a fourth gate valve; the pressure in the second load lock chamber is controlled to be reduced pressure or normal pressure; the pressure in the third cluster is controlled to be reduced pressure; the pressure in the fourth cluster is controlled to be normal pressure; the third cluster includes a third delivery device, a plurality of film formation apparatuses, an etching apparatus, and a plasma treatment apparatus; and the second cluster can include a fourth delivery device, a plurality of apparatuses performing a lithography step, and a polishing apparatus.

The film formation apparatuses are preferably one or more selected from a sputtering apparatus, a CVD apparatus, and an ALD apparatus; the etching apparatus is preferably a dry etching apparatus; and the polishing apparatus is preferably a CMP apparatus.

As the plurality of apparatuses performing the lithography step, an application apparatus, a light-exposure apparatus, a development apparatus, and a baking apparatus can be included.

The first load lock chamber is connected to the second load lock chamber through a fifth gate valve and the transfer chamber.

A silicon wafer can be used as the substrate. A driver circuit can be provided in the silicon wafer, and a pixel circuit electrically connected to the driver circuit can be formed.

### Effect of the Invention

According to one embodiment of the present invention, manufacturing equipment of a display device that is capable of successively performing steps from formation of a pixel circuit up to formation of a light-emitting element without exposure to the air can be provided. Alternatively, manufacturing equipment of a display device that is capable of forming a light-emitting element without using a metal mask can be provided. Further alternatively, a manufacturing method of a display device can be provided.

Note that the description of these effects does not preclude the existence of other effects. One embodiment of the present invention does not need to have all these effects. Effects other than these can be derived from the description of the specification, the drawings, the claims, and the like.

### BRIEF DESCRIPTION OF THE DRAWINGS

FIG. 1 is a diagram illustrating manufacturing equipment.

FIG. 2A and FIG. 2B are diagrams illustrating a substrate delivery jig.

FIG. 3A to FIG. 3C are diagrams illustrating examples of the number of display devices taken out of one substrate.

FIG. 4A is a diagram illustrating the sizes of a through hole of a substrate delivery jig and a hand portion of a delivery device. FIG. 4B and FIG. 4C are diagrams illustrating the substrate delivery jig and the delivery device.

FIG. 5A is a diagram illustrating a substrate reversing device. FIG. 5B to FIG. 5D are diagrams illustrating the substrate reversing device and a substrate delivery jig.

FIG. 6A to FIG. 6C are diagrams illustrating substrate reversing operation.

FIG. 7A to FIG. 7C are diagrams illustrating substrate reversing operation.

FIG. 8A is a diagram illustrating an evaporation apparatus. FIG. 8B is a diagram illustrating a dry etching apparatus.

FIG. 9 is a diagram illustrating manufacturing equipment.

FIG. 10A to FIG. 10D are diagrams each illustrating substrates placed on a substrate delivery jig.

FIG. 11A to FIG. 11C are diagrams illustrating a method for placing a substrate on a substrate delivery jig.

FIG. 12 is a diagram illustrating a display device.

FIG. 13A to FIG. 13C are diagrams each illustrating a display device.

FIG. 14A to FIG. 14D are diagrams illustrating a manufacturing method of a display device.

FIG. 15A to FIG. 15D are diagrams illustrating the manufacturing method of a display device.

FIG. 16A to FIG. 16D are diagrams illustrating the manufacturing method of a display device.

FIG. 17 is a diagram illustrating manufacturing equipment.

FIG. 18 is a diagram illustrating manufacturing equipment.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

### Embodiment 1

In this embodiment, manufacturing equipment of a display device of one embodiment of the present invention will be described with reference to drawings.

One embodiment of the present invention is manufacturing equipment that is mainly used to form a display device including a light-emitting element (also called a light-emitting device) such as an organic EL element. A lithography step is preferably used to downscale the organic EL element or to increase the area occupied by the organic EL element in a pixel. However, the reliability is impaired when impurities such as water, oxygen, and hydrogen enter the organic EL element. Therefore, some ingenuity is necessary; for example, the atmosphere needs to be controlled to have a low dew point from the manufacturing stage.

The manufacturing equipment of one embodiment of the present invention is capable of successively performing a film formation step, a lithography step, an etching step, and a sealing step for formation of an organic EL element without exposure to the air. Accordingly, a downscaled organic EL element with high luminance and high reliability can be formed.

The manufacturing equipment of one embodiment of the present invention includes a manufacturing apparatus for formation of a pixel circuit that drives an organic EL element. Accordingly, formation from the pixel circuit up to the organic EL element can be performed successively, so that a display device with a high yield and high reliability can be manufactured.

A silicon wafer can be used as a support substrate where a pixel circuit and an organic EL element are formed. A silicon wafer where a driver circuit and the like are formed in advance is used as a support substrate, whereby a pixel circuit can be formed over the driver circuit. Accordingly, a display device with a narrow bezel that is suitable for AR or VR can be formed. The silicon wafer is preferably ϕ8 inches or more (e.g., ϕ12 inches).

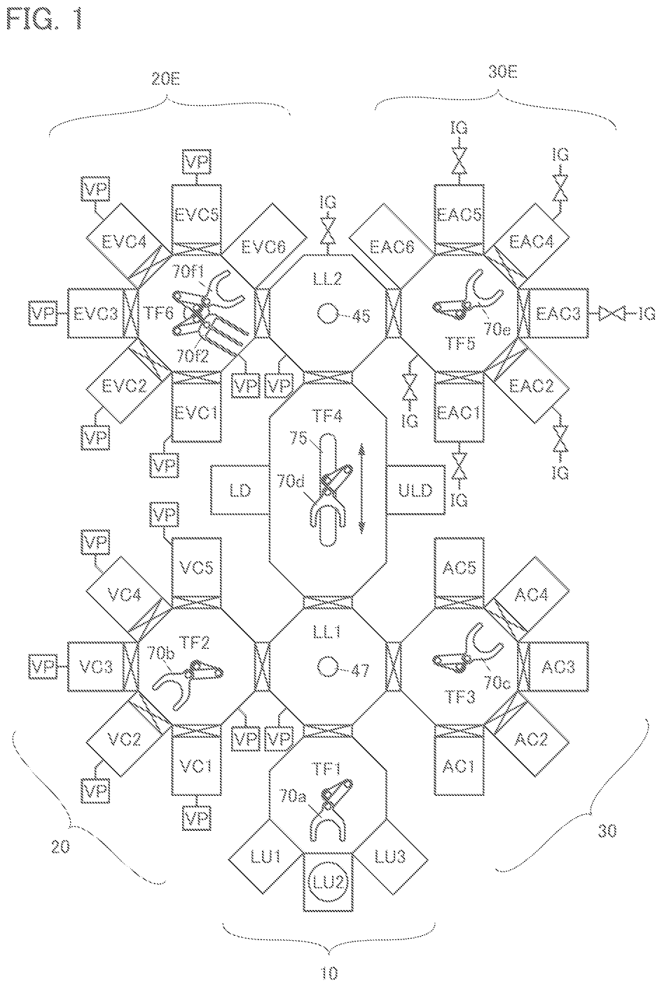

FIG. 1 is a diagram illustrating the manufacturing equipment of a display device of one embodiment of the present invention. The manufacturing equipment includes a manufacturing apparatus of a light-emitting device and a manufacturing apparatus of a pixel circuit.

<Manufacturing Apparatus of Light-Emitting Device>

The manufacturing apparatus of a light-emitting device includes a cluster 20E, a cluster 30E, and a load lock chamber LL2. In this specification, a group of apparatuses that shares a delivery device or the like is called a cluster. The cluster 20E includes a group of apparatuses for performing a vacuum process (a process under reduced pressure). The cluster 30E includes a group of apparatuses for performing a process under a controlled atmosphere.

<Cluster 20E>

The cluster 20E includes a transfer chamber TF6 and vacuum process apparatuses EVC. The number of vacuum process apparatuses EVC, which is six (vacuum process apparatuses EVC1 to EVC6) in the example illustrated in FIG. 1, may be one or more depending on the purpose. A vacuum pump VP is connected to each vacuum process apparatus EVC, and a gate valve is provided between each vacuum process apparatus EVC and the transfer chamber TF6. Thus, processes such as film formation and etching can be performed in parallel in the vacuum process apparatuses EVC.

Note that the vacuum process means treatment in an environment where the pressure is controlled to be reduced pressure. Thus, the vacuum process includes treatment with introduction of a process gas and pressure control, besides treatment under high vacuum.

The transfer chamber TF6 is also provided with an independent vacuum pump VP, so that cross-contamination during processes performed in the vacuum process apparatuses EVC can be prevented. Like the vacuum process apparatus EVC6 illustrated in FIG. 1, a vacuum process apparatus does not necessarily have a gate valve between it and the transfer chamber TF6.

The transfer chamber TF6 is connected to the load lock chamber LL2 through a gate valve. In the transfer chamber TF6, delivery devices 70f1 and 70f2 are provided. The delivery device 70f1 can deliver a substrate placed in the load lock chamber LL2 to the vacuum process apparatus EVC. The delivery device 70f2 can deliver a substrate using a substrate delivery jig described later. Note that either one of the delivery devices 70f1 and 70f2 may be provided.

As the vacuum process apparatus EVC, film formation apparatuses such as an evaporation apparatus, a sputtering apparatus, a CVD (Chemical Vapor Deposition) apparatus, and an ALD (Atomic Layer Deposition) apparatus can be used. As the CVD apparatus, a thermal CVD apparatus using heat, a PECVD apparatus (Plasma Enhanced CVD apparatus) using plasma, or the like can be used. As the ALD apparatus, a thermal ALD apparatus using heat, a PEALD apparatus (Plasma Enhanced ALD apparatus) using a plasma-enhanced reactant, or the like can be used. A dry etching apparatus or the like can be used as an etching apparatus. Alternatively, an auxiliary mechanism, such as a device detaching a substrate delivery jig or a substrate reversing device, may be employed as the vacuum process apparatus EVC. Such an auxiliary mechanism can be employed as, for example, the vacuum process apparatus EVC6, which does not have a gate valve between it and the transfer chamber TF6.

<Cluster 30E>

The cluster 30E includes a transfer chamber TF5 and normal-pressure process apparatuses EAC that mainly performs steps under normal pressure. The number of normal-pressure process apparatuses EAC, which is six (normal-pressure process apparatuses EAC1 to EAC6) in the example illustrated in FIG. 1, may be one or more depending on the purpose. Note that the pressure under which the normal-pressure process apparatus EAC performs a step is not limited to normal pressure and may be controlled to be slightly lower or higher than normal pressure. In the case where a plurality of normal-pressure process apparatuses EAC are provided, they may have different atmospheric pressures.

Valves for introducing an inert gas (IG) are connected to the transfer chamber TF5 and the normal-pressure process apparatuses EAC, whereby the atmosphere therein can be controlled to be an inert gas atmosphere. Examples of the inert gas that can be used include nitrogen and noble gases such as argon and helium. In addition, the inert gas preferably has a low dew point (e.g., −50° or lower). By performing a step in an inert gas atmosphere with a low dew point, the entry of impurities can be prevented, thereby forming a highly reliable organic EL element.

In the example illustrated in FIG. 1, the normal-pressure process apparatuses EAC1 to EAC5 are each connected to the transfer chamber TF5 through a gate valve. Providing the gate valve makes it possible to control atmospheric pressure, control the kind of an inert gas, and prevent cross-contamination, for example. In the case where they do not need to be strictly controlled, connection to the transfer chamber TF5 without through a gate valve may be employed as in the normal-pressure process apparatus EAC6.

The transfer chamber TF5 is connected to the load lock chamber LL2 through a gate valve. A delivery device 70e is provided in the transfer chamber TF5, whereby a substrate placed in the load lock chamber LL2 can be delivered to the normal-pressure process apparatus EAC.

As the normal-pressure process apparatuses EAC, apparatuses for performing a lithography step can be used. For example, in the case where a photolithography step is performed, a resin (photoresist) application apparatus, a light-exposure apparatus, a development apparatus, a baking apparatus, and the like can be employed. In the case where a nanoimprint lithography step is performed, a resin (e.g., UV curable resin) application apparatus, a nanoimprint apparatus, and the like can be employed. Alternatively, depending on the intended use, a cleaning apparatus, a wet etching apparatus, an application apparatus, a resist stripping apparatus, a counter substrate bonding apparatus, and the like may be employed as the normal-pressure process apparatuses EAC.

The load lock chamber LL2 is provided with a valve for introducing an inert gas and a vacuum pump VP. Thus, the pressure in the load lock chamber LL2 can be controlled to be reduced pressure or the atmosphere therein can be controlled to be an inert gas atmosphere. For example, a substrate can be delivered from the cluster 20E to the cluster 30E as follows: the substrate is carried in from the cluster 20E with the pressure in the load lock chamber LL2 reduced, the atmosphere in the load lock chamber LL2 is set to an inert gas atmosphere, and then the substrate is carried out into the cluster 30E.

In the load lock chamber LL2, a substrate rotation mechanism 45 by which the substrate delivered is rotated about the Z-axis (the axis perpendicular to the center of the top surface of the substrate) is provided. The substrate rotation mechanism 45 enables the orientation of a notch or an orientation flat to be aligned when a silicon wafer used as a substrate is carried in and out.

<Manufacturing Apparatus of Pixel Circuit>

The manufacturing apparatus of a pixel circuit includes a load/unload unit 10, a cluster 20, a cluster 30, and a load lock chamber LL1. The cluster 20 includes a group of apparatuses for performing a vacuum process (a process under reduced pressure). The cluster 30 includes a group of apparatuses for performing a process under normal pressure. Note that the descriptions of parts of the cluster 20 that are in common with the cluster 20E are omitted. In addition, the descriptions of parts of the cluster 30 that are in common with the cluster 30E are omitted.

<Load/Unload Unit>

The load/unload unit 10 includes load/unload chambers LU (load/unload chambers LU1, LU2, and LU3) and a transfer chamber TF1. The transfer chamber TF1 is connected to the load/unload chambers LU. The transfer chamber TF1 is connected to the load lock chamber LL1 through a gate valve. A delivery device 70a is provided in the transfer chamber TF1, whereby a substrate placed in the load/unload chamber LU can be delivered to the load lock chamber LL1.

A gate valve may be provided between the load/unload chamber LU and the transfer chamber TF1. Although FIG. 1 illustrates the load/unload chamber LU as an example, a load chamber and an unload chamber may be separately provided.

<Cluster 20>

The cluster 20 includes a transfer chamber TF2 and vacuum process apparatuses VC. The number of vacuum process apparatuses VC, which is six (vacuum process apparatuses VC1 to VC6) in the example illustrated in FIG. 1, may be one or more depending on the purpose.

The transfer chamber TF2 is connected to the load lock chamber LL1 through a gate valve. A delivery device 70b is provided in the transfer chamber TF2. The delivery device 70b can transfer a substrate placed in the load lock chamber LL1 to the vacuum process apparatus VC.

As the vacuum process apparatus VC, film formation apparatuses such as a sputtering apparatus, a CVD apparatus, and an ALD apparatus, a plasma treatment apparatus, and the like can be employed. A dry etching apparatus or the like can be employed as an etching apparatus.

As the plasma treatment apparatus, a microwave excitation plasma treatment apparatus that can generate high-density plasma can be used, for example. The plasma treatment apparatus is used, for example, to supply oxygen to transistor components when a transistor in which an oxide semiconductor is used in a pixel circuit is formed.

<Cluster 30>

The cluster 30 includes normal-pressure process apparatuses AC that mainly perform steps under normal pressure and a transfer chamber TF3. The number of normal-pressure process apparatuses AC, which is six (normal-pressure process apparatuses AC1 to AC6) in the example illustrated in FIG. 1, may be one or more depending on the purpose. Although not illustrated, a valve for introducing an inert gas (IG) may be provided as in the cluster 30E to control the atmosphere to be an inert gas atmosphere.

The transfer chamber TF3 is connected to the load lock chamber LL1 through a gate valve. A delivery device 70c is provided in the transfer chamber TF3, whereby a substrate placed in the load lock chamber LL1 can be delivered to the normal-pressure process apparatus AC.

As the normal-pressure process apparatuses AC, apparatuses for performing a lithography step can be employed. For example, in the case where a photolithography step is performed, a resist (photoresist) application apparatus, a light-exposure apparatus, a development apparatus, a resist stripping apparatus, a baking apparatus, and the like may be employed; a polishing apparatus can also be provided.

As the polishing apparatus, a CMP (Chemical Mechanical Polishing) apparatus is preferably used. The polishing apparatus is used, for example, to planarize a formation surface of a transistor and the like included in a pixel circuit, to form an embedded plug, and to form an embedded wiring. Alternatively, depending on the intended use, a cleaning apparatus, a wet etching apparatus, and the like may be employed as the normal-pressure process apparatus AC.

The load lock chamber LL1 is connected to the load lock chamber LL2 through a gate valve, a transfer chamber TF4, and a gate valve. A load chamber LD and an unload chamber ULD can be connected to the transfer chamber TF4. In the load lock chamber LL1, a substrate rotation mechanism 47 that is the same as the substrate rotation mechanism 45 is provided.

The transfer chamber TF4 is provided with the unload chamber ULD, whereby a substrate where formation treatment of a light-emitting device has been completed can be removed without returning the substrate to the load/unload unit 10, and contamination due to a material of the light-emitting device, or the like can be prevented, for example. The load chamber enables a substrate to be loaded without through the load/unload unit 10 in the case where only formation treatment of a light-emitting device is performed, for example. The load/unload unit 10 enables a substrate where only formation treatment of a pixel circuit or the like has been performed to be removed.

A delivery device 70d is provided in the transfer chamber TF4, whereby a substrate placed in the load lock chamber LL1 can be delivered to the load lock chamber LL2. Alternatively, a substrate can be carried in from the load chamber LD and carried out to the unload chamber ULD. The delivery device 70d is self-propelled and can move along a rail 75. Note that the self-propelled structure may not be needed depending on the specifications of the transfer chamber TF4 and the delivery device 70d.

A gate valve may be provided between the transfer chamber TF4 and each of the load chamber LD and the unload chamber ULD. The load lock chamber LL1 and the transfer chamber TF4 may be provided with a valve for introducing an inert gas (IG), so that the atmosphere therein can be controlled to be an inert gas atmosphere. The transfer chamber TF4 may also be provided with a vacuum pump VP.

The manufacturing equipment with the above-described structure is capable of performing steps described below. First, a substrate is carried in from the load/unload chamber LU to the cluster 20 to perform a film formation step. A silicon wafer that is a substrate is provided with a pixel driver circuit or the like as needed. Then, the substrate is delivered from the cluster 20 to the cluster 30 to perform a lithography step. Subsequently, the substrate is delivered from the cluster 30 to the cluster 20 to perform an etching step. These steps are repeated several times as needed, so that a structure (a pixel circuit that includes a transistor including an oxide semiconductor, and the like) is formed. Then, a film formation step for formation of a protective film covering the structure is performed in the cluster 20. Subsequently, the substrate is carried out from the cluster 20E to the load lock chamber LL1.

Next, the substrate is carried in from the load lock chamber LL1 to the cluster 20E through the load lock chamber LL2 to perform a film formation step. Then, the substrate is delivered from the cluster 20E to the cluster 30E to perform a lithography step. Subsequently, the substrate is delivered from the cluster 30E to the cluster 20E to perform an etching step. These steps are repeated several times as needed, so that a structure (a light-emitting element such as an organic EL element) is formed over the pixel circuit. Then, a film formation step for formation of a protective film covering the structure is performed in the cluster 20E. Subsequently, the substrate is carried out from the cluster 20E to the unload chamber ULD or the load/unload chamber LU.

In the above manner, the light-emitting element, such as an organic EL element, sealed with the protective film can be carried out into the air without being exposed to the air. That is, in the case where the organic EL element is formed as the structure, the entry of impurities contained in the air can be inhibited, thereby enhancing the reliability. Moreover, formation steps of a light-emitting device are performed successively from the formation steps of the pixel circuit, so that a display device with a high yield and high reliability can be manufactured.

<Substrate Delivery Jig>

The orientation (a face-up mode or a face-down mode) of a substrate to be placed may differ between the vacuum process apparatuses. Since a substrate is placed on one of electrodes that are opposite each other in a sputtering apparatus, a CVD apparatus, an etching apparatus, or the like, either a face-up mode or a face-down mode can be adopted.

Therefore, all of the vacuum process apparatuses VC in the cluster 20 can have a structure in which a substrate is placed in a face-up mode. In the face-up mode, a substrate can be delivered on a hand portion of the delivery device with its surface where a structure is to be formed facing up and can be easily placed on a stage (e.g., an electrode) in the vacuum process apparatus VC.

Meanwhile, an evaporation apparatus that is a vacuum process apparatus EVC included in the cluster 20E requires an evaporation source such as a crucible because an evaporation material is often powder. For this reason, it is preferable that an evaporation source be placed on the lower side and a substrate be placed on the upper side in a face-down mode. Therefore, the substrate needs to be reversed between steps in some cases.

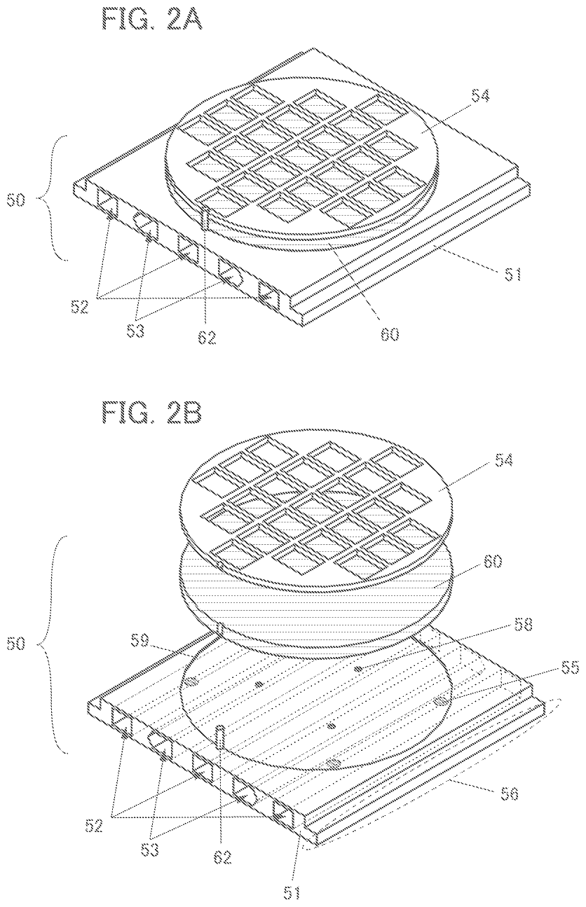

In the face-down mode, the substrate needs to be delivered such that the hand portion of the delivery device does not touch the substrate surface. It is thus preferable to use a substrate delivery jig illustrated in FIG. 2A and FIG. 2B. The substrate delivery jig includes a jig 51 and a jig 54. FIG. 2A illustrates a substrate 60 held between the jig 51 and the jig 54, and the structure is called a work substrate 50 in this specification. By being held between the jig 51 and the jig 54, the substrate 60 can be prevented from being warped, which is effective particularly when the substrate is placed in a face-down mode.

The jig 54 includes openings and holds the substrate 60 using the portion other than the openings. Structures such as light-emitting elements are formed in the openings; thus, the size and shape of the opening are adjusted depending on the purpose. For example, the size of the opening can be determined depending on the size of a light-exposure region described below.

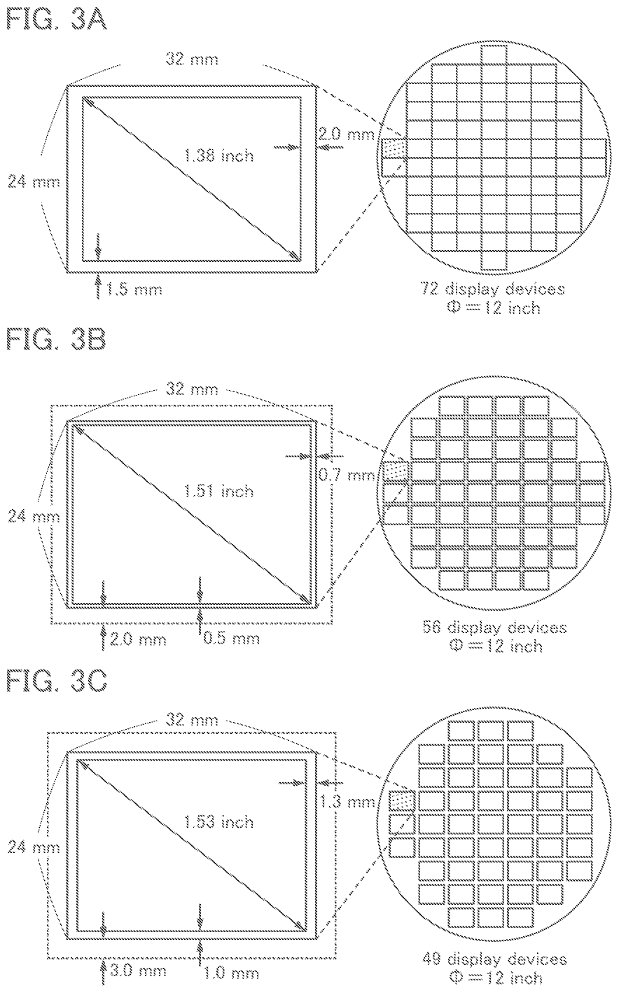

FIG. 3A to FIG. 3C illustrate examples of the number of display devices taken out of one substrate (e.g., silicon wafer) with a diameter Φ of 12 inches. In FIG. 3A to FIG. 3C, the number of display devices is estimated on the assumption that an external connection terminal is extracted from a rear surface with the use of a through electrode. Thus, a display region can be large. Note that a pad may be provided in the light-exposure region. In that case, the display region is reduced in size, but an effect of reducing the manufacturing cost for the structure of extracting the external connection terminal is obtained.

FIG. 3A to FIG. 3C each illustrate an example of a case where the aspect ratio of a display region is 4:3.

FIG. 3A is an example where a sealing region is provided inside a light-exposure region (32 mm×24 mm) of a light-exposure apparatus. In the example of FIG. 3A, the width of the sealing region in the vertical direction is 1.5 mm and that in the horizontal direction is 2.0 mm. In this case, the display region has a size of 28 mm×21 mm (an aspect ratio of 4:3) and a diagonal size of approximately 1.38 inches. The number of display devices taken out of one substrate is 72. When the width of the sealing region in the vertical direction is 2.0 mm and that in the horizontal direction is 2.65 mm, the display region has a size of 26.7 mm×20 mm (an aspect ratio of 4:3) and a diagonal size of approximately 1.32 inches. Moreover, when the width of the sealing region in the vertical direction is 3.0 mm and that in the horizontal direction is 4.0 mm, the display region has a size of 24 mm×18 mm (an aspect ratio of 4:3) and a diagonal size of approximately 1.18 inches. In each case, the number of display devices taken out of one substrate is 72.

FIG. 3B and FIG. 3C each illustrate an example where a sealing region is provided outside a region (32 mm×24 mm) exposed by a light-exposure apparatus. In this case, the region except a space for the sealing region is exposed to light. A marker region is provided inside the light-exposed region. In the example illustrated in FIG. 3B, the width of the marker region in the vertical direction is 0.5 mm and that in the horizontal direction is 0.7 mm, and the width of the sealing region is 2.0 mm. In this case, the display region of the display device has a diagonal size of approximately 1.51 inches. The number of display devices taken out of one substrate is 56. When the width of the marker region in the vertical direction is 1.0 mm and that in the horizontal direction is 1.3 mm, the display region has a diagonal size of approximately 1.45 inches. In the example illustrated in FIG. 3C, the width of the marker region in the vertical direction is 0.5 mm and that in the horizontal direction is 0.7 mm, and the width of the sealing region is 3.0 mm. In this case, the display region of the display device has a diagonal size of approximately 1.51 inches, which is the same as that in FIG. 3B. The number of display devices taken out of one substrate is 49, which is lower by approximately 13% than that in FIG. 3B.

FIG. 2B is a diagram of the jig 51, the substrate 60, and the jig 54 that are separated in the vertical direction. The jig 51 and the jig 54 are preferably formed using a hard material such as a metal, ceramic, or a cermet. Alternatively, the jigs may be formed using a combination of these materials. FIG. 2B illustrates an example in which the substrate 60 is held between the jig 51 provided with a magnet and the jig 54 formed using a magnetic metal.

As another structure, only a part of the jig 54 that faces a magnet 55 may be provided with a magnetic metal and the other part may be formed using ceramic or the like. The magnet 55 may be provided on the jig 51 side. Alternatively, the magnet 55 may be provided in both the jig 51 and the jig 54. Note that the substrate 60 may be held between the jig 51 and the jig 54 with the use of a spring or any other structure.

The jig 51 can be provided with a through hole 58 for a pusher pin and a pin 62 for alignment. A pusher pin put through the through hole 58 enables the substrate 60 to be lifted and the substrate 60 to be easily placed on or removed from the jig 51. Rough alignment can be performed in such a manner that a notch portion of the substrate 60 is aligned with the pin 62 and the substrate 60 is aligned with a depression portion 59. Details of placement of the substrate 60 on the jig 51 will be described later.

It is preferable that, as illustrated in FIG. 2B, the jig 51 be rectangle when viewed from above and have a flat-plate portion and that the flat-plate portion have a size larger than or equal to the diameter of the substrate 60. A projection 56 is provided in each of a first end portion that is perpendicular to the top surface of the flat-plate portion and a second end portion that is opposite the first end portion. The projection 56 can be used at the time of face-down placement, which will be described later.

A through hole 52 and a through hole 53 are provided between a third end portion that is perpendicular to the first end portion and a fourth end portion that is opposite the third end portion.

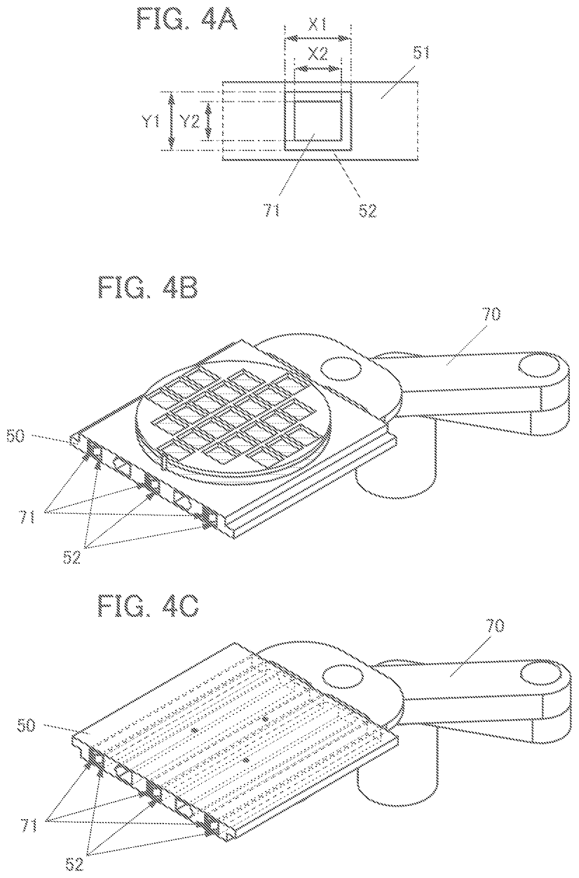

Here, FIG. 4B illustrates comparison between the size of the through hole 52 and that of a hand portion 71 of the delivery device 70. When the inner size of a cross section of the through hole 52 perpendicular to the major axis is X1×Y1 and the outer size of a cross section of the hand portion 71 perpendicular to the major axis is X2×Y2, X1>X2 and Y1>Y2 are satisfied. Accordingly, the hand portion 71 of the delivery device 70 can be inserted into the through hole 52 as illustrated in FIG. 4A.

As illustrated in FIG. 4C, even the work substrate 50 reversed can be delivered with the hand portions 71 of the delivery device 70 inserted into the through holes 52. Accordingly, the hand portion 71 does not touch a surface of the substrate 60 or the jig 54, which can prevent damage to and contamination of the surface of the substrate 60 and peeling of a film attached to the jig 54, for example.

The height (Y1) of the inner size of the through hole 52 is larger than the thickness (Y2) of the hand portion 71, whereby the hand portion 71 of the delivery device 70 can be inserted into and removed from the through hole 52 of the fixed work substrate 50 through only operation of the delivery device 70. The number of through holes 52, which is three in FIG. 4B and FIG. 4C, may be two or four or more. Note that the substrate delivery jig described in this embodiment is an example, and a substrate delivery jig with another structure may be used.

<Substrate Reversing Device>

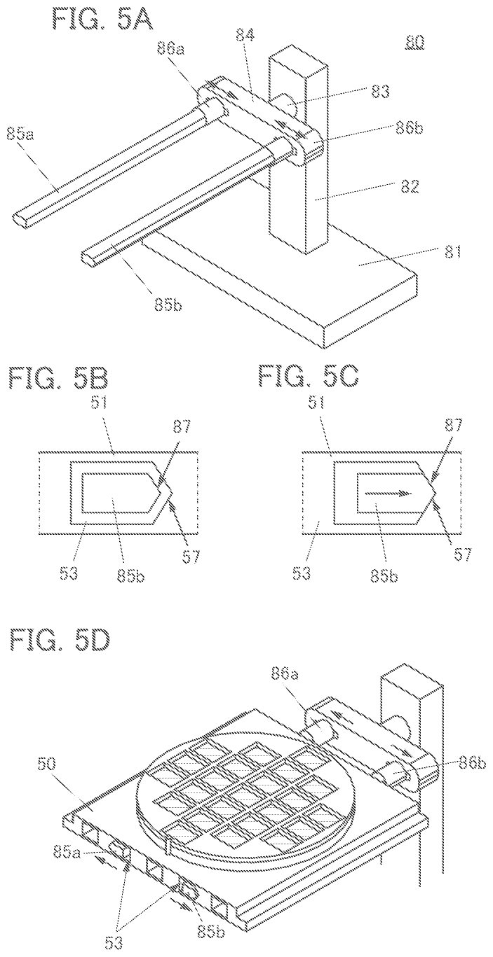

Into the through holes 53, hand portions 85a and 85b of a substrate reversing device 80 illustrated in FIG. 5A are inserted. The substrate reversing device 80 includes a pillar 82 fixed on a support 81, a rotation mechanism 83 fixed to the pillar 82, and a rotation portion 84 fixed to a rotating shaft of the rotation mechanism 83. The rotation portion 84 includes horizontal movement mechanisms 86a and 86b. The hand portion 85a is connected to the horizontal movement mechanism 86a, and the hand portion 85b is connected to the horizontal movement mechanism 86b.

FIG. 5B illustrates a cross section of the hand portion 85b of the substrate reversing device 80 perpendicular to the major axis and a cross section of the through hole 53 perpendicular to the major axis. Part of the cross section of the hand portion 85b perpendicular to the major axis includes a protruding shape portion 87. Part of the cross section of the through hole 53 perpendicular to the major axis includes a depressed shape portion 57.

As illustrated in FIG. 5C, moving the horizontal movement mechanism 86b with a horizontal movement mechanism such that the protruding shape portion 87 and the depressed shape portion 57 are in contact with each other brings the protruding shape portion 87 and the depressed shape portion 57 into close contact with each other. As illustrated in FIG. 5D, the hand portion 85a with a line-symmetric structure is moved in a similar manner, whereby the hand portions 85a and 85b can be fixed to the work substrate 50. The protruding shape portion 87 and the depressed shape portion 57 may each have a curvature as long as these portions can be brought into close contact with each other.

FIG. 5D illustrates a structure in which the protruding shape portion 87 and the depressed shape portion 57 described above come into contact with each other when the hand portion 85a and the hand portion 85b move away from each other; however, a structure may be employed in which the protruding shape portion 87 and the depressed shape portion 57 described above come into contact with each other when the hand portion 85a and the hand portion 85b move close to each other.

Next, operation for reversing the work substrate 50 is described. Note that the work substrate 50 is assumed to be on standby with the hand portions 71 of the delivery device 70 inserted into the through holes 52 in advance and a surface of the substrate 60 is assumed to face upward.

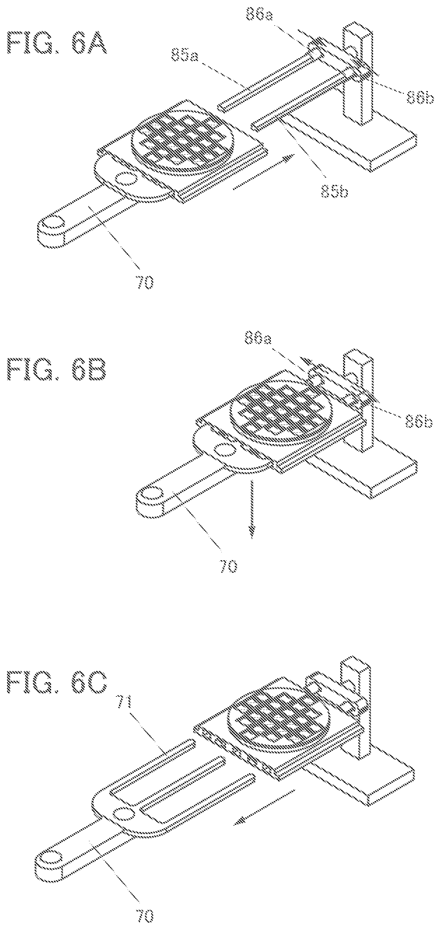

First, the hand portion 85a and the hand portion 85b of the substrate reversing device 80 are moved close to each other, and the delivery device 70 is operated such that the hand portion 85a and the hand portion 85b are inserted into the through holes 53 (see FIG. 6A).

Subsequently, the hand portion 85a and the hand portion 85b are moved away from each other, so that the work substrate 50 is fixed to the hand portion 85a and the hand portion 85b. Then, the hand portions 71 of the delivery device 70 are slightly lowered to the height where the hand portions 71 do not touch the inner walls of the through holes 52 (see FIG. 6B). Then, the hand portions 71 are removed from the through holes 52 (see FIG. 6C).

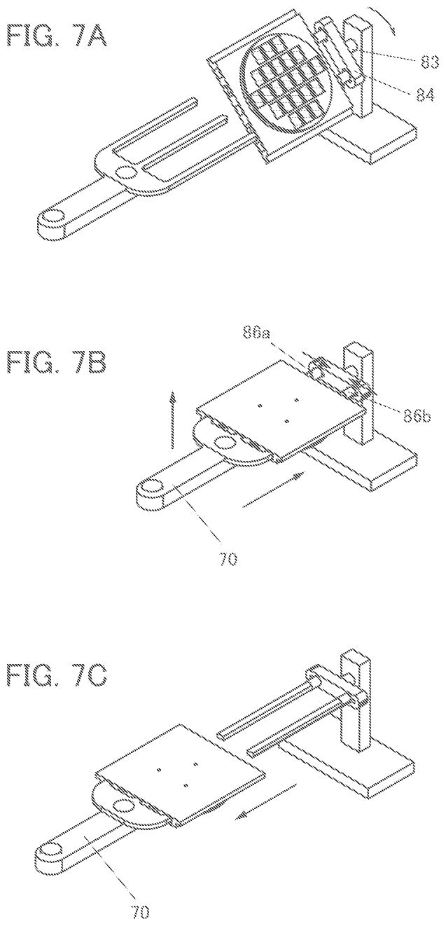

Next, the rotation mechanism 83 rotates the rotation portion 84 (see FIG. 7A), and after the reversal, the hand portions 71 of the delivery device are inserted into the through holes 53. Subsequently, the hand portion 85a and the hand portion 85b of the substrate reversing device 80 are moved close to each other, so that the hand portion 85a and the hand portion 85b are unfixed from the work substrate 50. Then, the hand portions 71 of the delivery device 70 are slightly raised to the height where the hand portions 71 touch the inner walls of the through holes 52 (see FIG. 7B).

Then, the hand portions 71 are moved backward, so that the work substrate 50 is removed from the hand portion 85a and the hand portion 85b of the substrate reversing device 80. The operation for reversing the work substrate 50 is as described above. Note that similar operation is performed to return the work substrate to the state illustrated in FIG. 6A from the state illustrated in FIG. 7C.

<Vacuum Process Apparatus EVC>

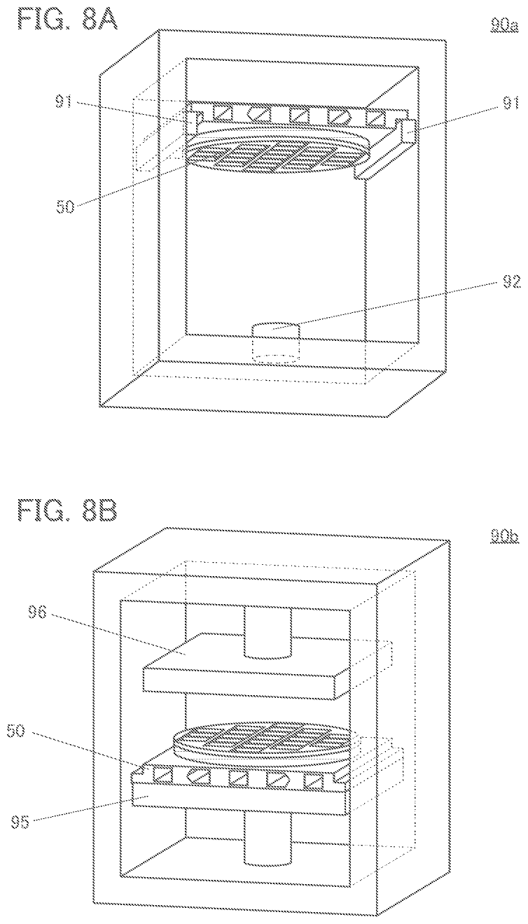

Next, placement of the work substrate 50 in the vacuum process apparatus EVC will be described. FIG. 8A is a diagram illustrating the vacuum process apparatus EVC in which the work substrate 50 is placed in a face-down mode; here, an evaporation apparatus 90a is illustrated as an example. For clarity, this diagram omits a gate valve

The evaporation apparatus 90a includes a pair of rails 91 fixed to a chamber at a position higher than an evaporation source 92 (crucible). The work substrate 50 is placed such that side surfaces of the projections 56 are put on the rails 91, whereby the work substrate 50 can be placed in a face-down mode in the chamber of the evaporation apparatus 90a.

Like the evaporation apparatus 90a illustrated in FIG. 8A, a sputtering apparatus employs the structure in which the work substrate 50 is placed on the rails 91, so that the substrate can be placed in a face-down mode.

FIG. 8B is a diagram illustrating a vacuum process apparatus EVC in which the work substrate 50 is placed in a face-up mode; here a dry etching apparatus 90b is illustrated as an example. For clarity, this diagram omits a gate valve.

The dry etching apparatus 90b is of a parallel plate type and includes a cathode 95 (stage) and an anode 96. The work substrate 50 is placed such that the jig 51 side thereof is on and in contact with the stage, whereby the work substrate 50 can be placed in a face-up mode in a chamber of the dry etching apparatus 90b. Since the work substrate 50 can be carried in and out through only operation of the delivery device 70, a pusher pin for lifting the substrate or the like is not needed here.

A CVD apparatus, an ALD apparatus, and the like in which the work substrate 50 is placed in a face-up mode can also employ the structure in which the work substrate 50 is placed on a stage as in the dry etching apparatus 90b illustrated in FIG. 8B.

The use of the manufacturing equipment of one embodiment of the present invention described above enables a film formation step, a lithography step, an etching step, and a sealing step to be performed successively. Accordingly, a downscaled organic EL element with high luminance and high reliability can be formed.

<Compatible with Large Size>

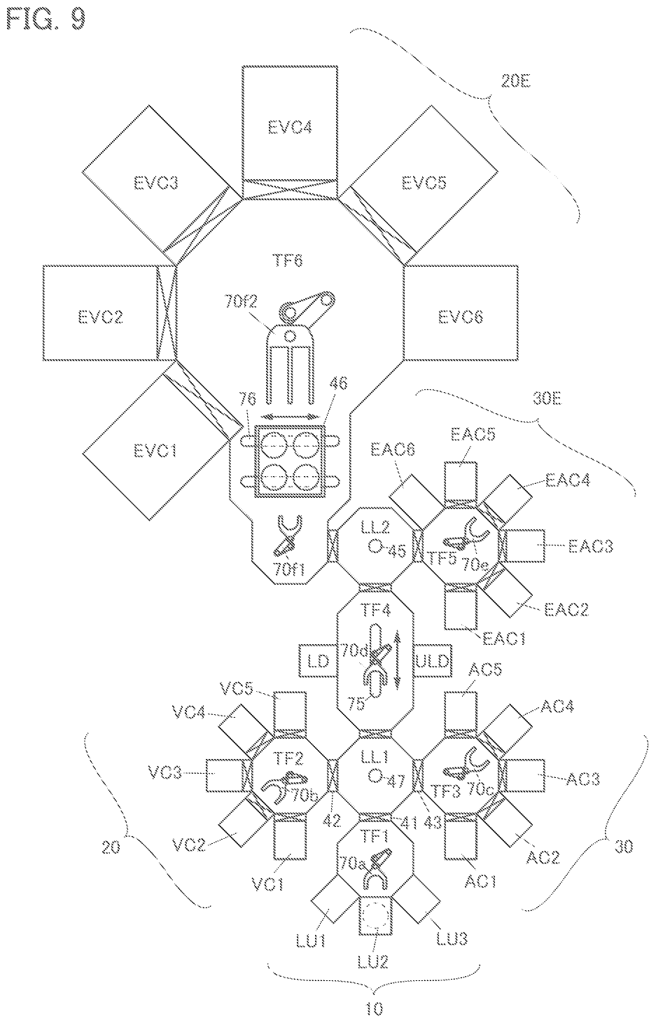

As illustrated in FIG. 9, the cluster 20E may be compatible with large size such that a plurality of substrates can be batch processed. With the cluster 20E compatible with large size, throughput can be increased. Alternatively, the cluster 20E can be used effectively in the case where an apparatus compatible with large size is already included. The structure illustrated in FIG. 9 can be the same as that illustrated in FIG. 1 except for the cluster 20E.

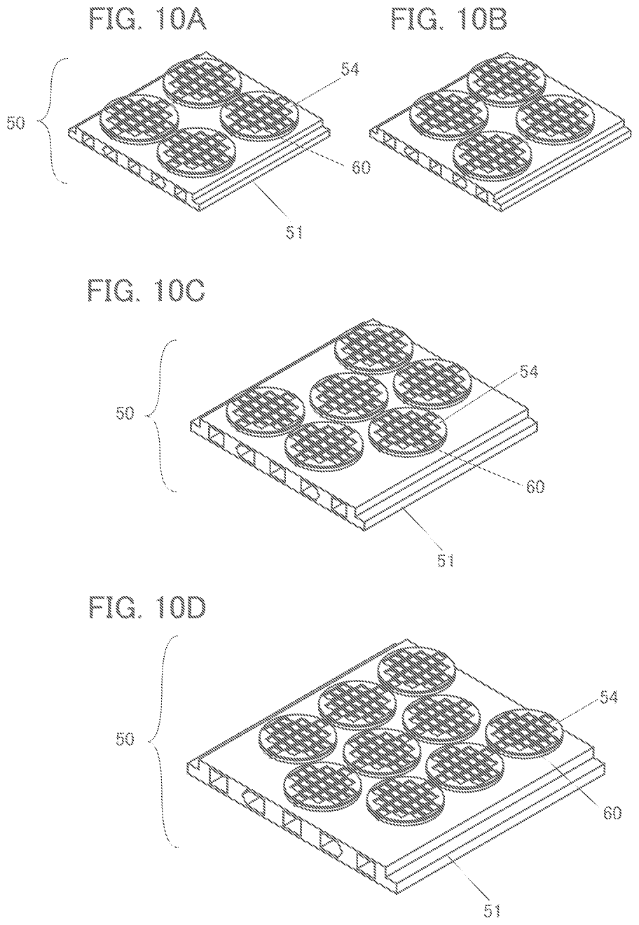

In the case of the structure, a delivery jig corresponds to a plurality of substrates 60. FIG. 10A illustrates an example in which four substrates 60 are aligned and placed on the jig 51. As illustrated in FIG. 10B, a structure in which the substrates 60 are placed in a nearly staggered manner may be employed. FIG. 10B illustrates a structure in which six substrates 60 are placed in a staggered manner and FIG. 10C illustrates a structure in which nine substrates 60 are placed in a staggered manner. By placing the substrates 60 in a staggered manner, the jig 51 can be reduced in size. Alternatively, a larger number of substrates 60 can be placed on the jig 51.

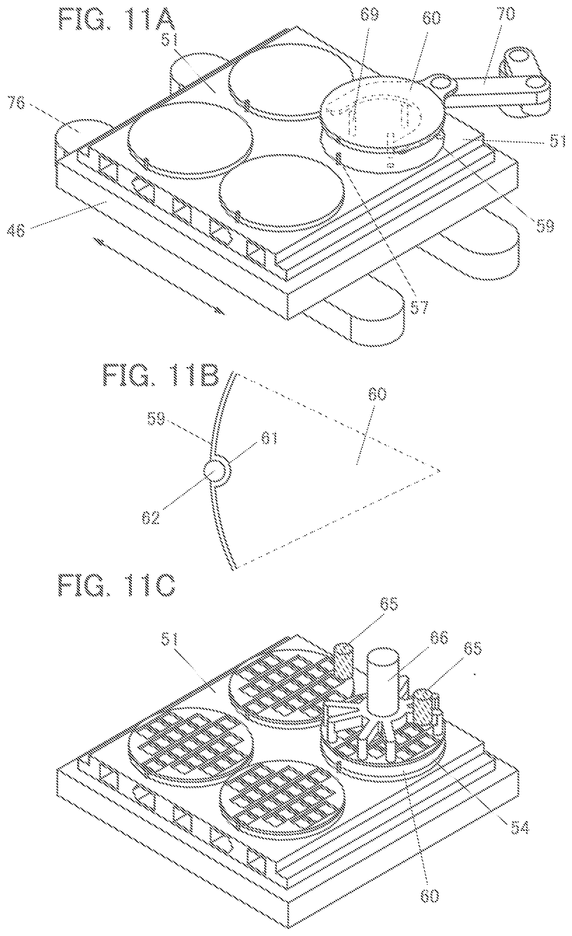

FIG. 11A is a diagram illustrating placement of the substrate 60 on the jig 51. The jig 51 is placed on a stage 46. The stage 46 can move in the horizontal direction along rails 76 and can move according to the movable range of the delivery device 70.

First, the substrate 60 is set on a hand of the delivery device 70 such that a notch is positioned on the front side. The position of the notch can be adjusted by rotation movement of the substrate rotation mechanism 45 of the load lock chamber LL2.

Next, the substrate 60 is delivered to the position where the jig 51 is placed, a pusher pin 69 is raised to lift the substrate 60, and a hand of the delivery device 70 is pulled out. Then, the pusher pin 69 is lowered to be set to the depression portion 59. In the above operation, the pin 62 and a notch 61 of the substrate 60 are preferably distant from each other so that they are not in contact with each other, as illustrated in a top view of FIG. 11B. With such a structure, the notch 61 and the pin 62 are in contact and do not move even when the substrate 60 moves within the range of clearance of the depression portion 59, preventing large movement of the substrate 60. In other words, rough alignment is possible with the depression portion and the pin 62.

Next, as illustrated in FIG. 11C, the jig 54 is held by a delivery device 66 and delivered onto the substrate 60. Here, a marker provided in the substrate 60 and a marker provided in the jig 54 are monitored with a camera 65 to perform more precise alignment. Then, the jig 54 is lowered to be in close contact with the substrate 60 and is removed from the delivery device 66. The jig 54 can be held by the delivery device 66 with the use of an electrostatic chuck or an electromagnet, for example.

Through the above operation, a plurality of substrates 60 can be placed on the jig 51 and the jig 54 can be aligned and placed on the substrate 60. Note that the same operation can be performed in the case where the delivery jig illustrated in FIG. 2 is used.

This embodiment can be implemented in an appropriate combination with the structures described in the other embodiment.

### Embodiment 2

In this embodiment, specific examples of a transistor and a light-emitting element (an organic EL element) that are manufactured using the manufacturing equipment of a display device of one embodiment of the present invention will be described.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a white-light-emitting device that is combined with coloring layers (e.g., color filters) can be a light-emitting device for full-color display.

Structures of light-emitting devices can be classified roughly into a single structure and a tandem structure. A light-emitting device with a single structure includes one light-emitting unit between a pair of electrodes, and the light-emitting unit preferably includes one or more light-emitting layers. To obtain white light emission, two or more light-emitting layers are selected such that their emission colors are complementary colors. For example, when emission colors of a first light-emitting layer and a second light-emitting layer are complementary colors, the light-emitting device can be configured to emit white light as a whole. The same applies to a light-emitting device including three or more light-emitting layers.

A light-emitting device with a tandem structure includes two or more light-emitting units between a pair of electrode, and each light-emitting unit preferably includes one or more light-emitting layers. To obtain white light emission, the light-emitting device is configured to obtain white light by combining light from light-emitting layers of a plurality of light-emitting units. Note that the structure that can provide white light emission is similar to that of the single structure. In the light-emitting device with a tandem structure, an intermediate layer such as a charge-generation layer is preferably provided between the plurality of light-emitting units.

When the white light-emitting device (a single structure or a tandem structure) and a light-emitting device with an SBS structure are compared to each other, the light-emitting device with an SBS structure can have lower power consumption than the white light-emitting device. To reduce power consumption, a light-emitting device with an SBS structure is preferably used. In contrast, the white light-emitting device is preferable in terms of low manufacturing cost or high manufacturing yield because the manufacturing process of the white light-emitting device is simpler than that of a light-emitting device with an SBS structure.

The device with a tandem structure may include light-emitting layers that emit light of the same color (e.g., BB, GG, or RR). The tandem structure in which light is emitted from a plurality of layers requires high voltage for light emission but achieves the same emission intensity as a single structure with a smaller current value. Thus, the tandem structure enables current stress on each light-emitting unit to be reduced and the element lifetime to be extended.

### Structure Example

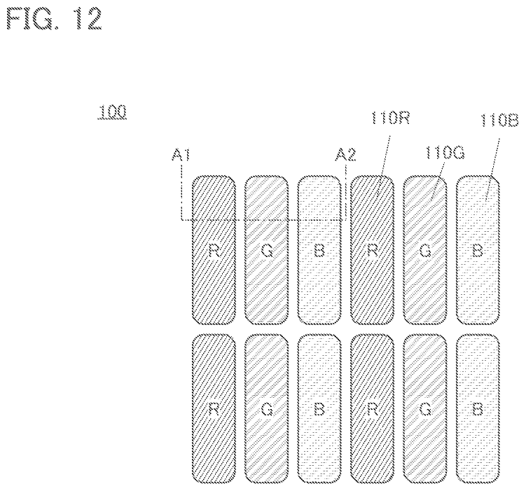

FIG. 12 is a schematic top view of a display device 100 of one embodiment of the present invention. The display device 100 includes a plurality of light-emitting elements 110R exhibiting red, a plurality of light-emitting elements 110G exhibiting green, and a plurality of light-emitting elements 110B exhibiting blue. In FIG. 12, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 12 illustrates what is called a stripe arrangement, in which light-emitting elements of the same color are arranged in one direction. Note that the arrangement method of the light-emitting elements is not limited thereto; another arrangement method such as a delta arrangement, a zigzag arrangement, or a PenTile arrangement may also be used.

As the light-emitting element 110R, the light-emitting element 110G, and the light-emitting element 110B, an EL element such as an OLED (Organic Light Emitting Diode) or a QLED (Quantum-dot Light Emitting Diode) is preferably used. Examples of light-emitting substances contained in the EL element include a substance that emits fluorescence (a fluorescent material), a substance that emits phosphorescence (a phosphorescent material), an inorganic compound (e.g., a quantum dot material), and a substance that exhibits thermally activated delayed fluorescence (a thermally activated delayed fluorescent (TADF) material).

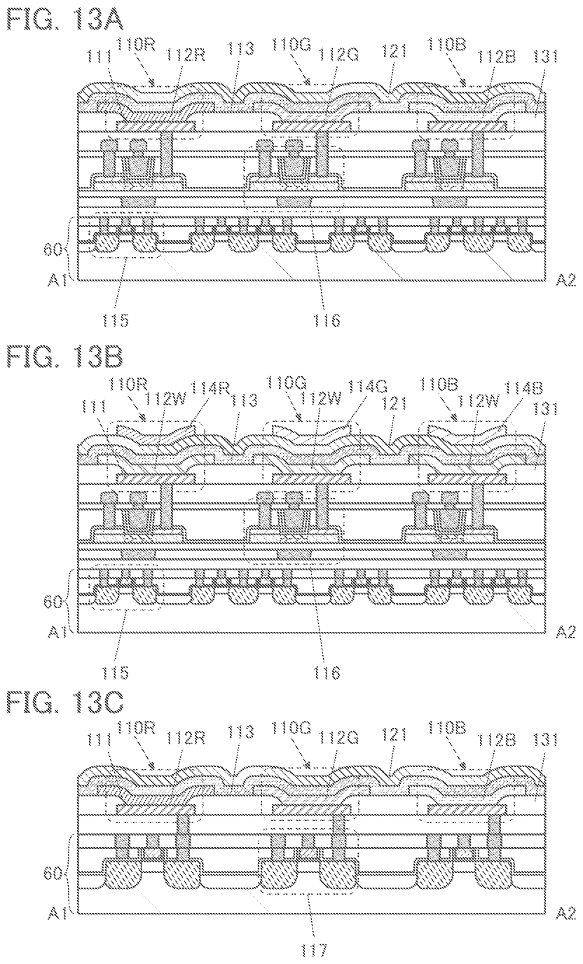

FIG. 13A is a schematic cross-sectional view taken along dashed-dotted line A1-A2 in FIG. 12.

FIG. 12 illustrates cross sections of the light-emitting element 110R, the light-emitting element 110G, and the light-emitting element 110B. Each of the light-emitting element 110R, the light-emitting element 110G, and the light-emitting element 110B is provided over a pixel circuit and includes a pixel electrode 111 and a common electrode 113.

The light-emitting element 110R includes an EL layer 112R between the pixel electrode 111 and the common electrode 113. The EL layer 112R contains at least a light-emitting organic compound that emits light with a peak in a red wavelength range. An EL layer 112G included in the light-emitting element 110G contains at least a light-emitting organic compound that emits light with a peak in a green wavelength range. An EL layer 112B included in the light-emitting element 110B contains at least a light-emitting organic compound that emits light with a peak in a blue wavelength range. Note that a structure in which the EL layer 112R, the EL layer 112G, and the EL layer 112B emit light of different colors may be referred to as an SBS (Side By Side) structure.

The EL layer 112R, the EL layer 112G, and the EL layer 112B may each include one or more of an electron-injection layer, an electron-transport layer, a hole-injection layer, and a hole-transport layer in addition to the layer containing a light-emitting organic compound (light-emitting layer).

The pixel electrode 111 is provided for each of the light-emitting elements. The common electrode 113 is provided as a continuous layer shared by the light-emitting elements. A conductive film that transmits visible light is used for one of the pixel electrode 111 and the common electrode 113, and a reflective conductive film is used for the other. When the pixel electrode 111 is a light-transmitting electrode and the common electrode 113 is a reflective electrode, a bottom-emission display device can be obtained; when the pixel electrode 111 is a reflective electrode and the common electrode 113 is a transparent electrode, a top-emission display device can be obtained. Note that when both the pixel electrode 111 and the common electrode 113 transmit light, a dual-emission display device can be obtained. In this embodiment, an example of manufacturing a top-emission display device is described.

The insulating layer 131 is provided to cover end portions of the pixel electrode 111. The end portions of the insulating layer 131 are preferably tapered.

The EL layer 112R, the EL layer 112G, and the EL layer 112B each include a region in contact with a top surface of the pixel electrode 111 and a region in contact with a surface of the insulating layer 131. End portions of the EL layer 112R, the EL layer 112G, and the EL layer 112B are positioned over the insulating layer 131.

As illustrated in FIG. 13A, there is a gap between two EL layers in the light-emitting elements of different colors. In this manner, the EL layer 112R, the EL layer 112G, and the EL layer 112B are preferably provided not to be in contact with each other. This effectively prevents unintentional light emission from being caused by current flowing through two adjacent EL layers. As a result, the contrast can be increased to achieve a display device with high display quality.

A protective layer 121 is provided over the common electrode 113 so as to cover the light-emitting element 110R, the light-emitting element 110G, and the light-emitting element 110B. The protective layer 121 has a function of preventing diffusion of impurities into the light-emitting elements from above. Alternatively, the protective layer 121 has a function of trapping (also called gettering) impurities (typically, impurities such as water and hydrogen) that may enter the light-emitting elements.

The protective layer 121 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 121.

The pixel electrode 111 is electrically connected to one of a source and a drain of a transistor 116. For example, a transistor including a metal oxide in a channel formation region (hereinafter, an OS transistor) can be used as the transistor 116. The OS transistor has higher mobility and more excellent electrical characteristics than amorphous silicon. Moreover, the OS transistor does not require a crystallization process required for a manufacturing process using polycrystalline silicon and can be formed in a wiring process or the like. Therefore, the OS transistor can be formed over a transistor 115 including silicon in a channel formation region (hereinafter, a Si transistor), which is formed in the substrate 60, without a bonding step.

Here, the transistor 116 is a transistor included in a pixel circuit and can be formed using the manufacturing equipment of one embodiment of the present invention. The transistor 115 is a transistor included in a driver circuit for the pixel circuit, or the like. In other words, the pixel circuit can be formed over the driver circuit, which enables formation of a display device with a narrow bezel.

As a semiconductor material used for an OS transistor, a metal oxide whose energy gap is greater than or equal to 2 eV, preferably greater than or equal to 2.5 eV, further preferably greater than or equal to 3 eV can be used.

In an OS transistor, a semiconductor layer has a large energy gap, and thus the OS transistor has an extremely low off-state current of several yA/μm (current per micrometer of a channel width). An OS transistor has the following feature different from that of a Si transistor: impact ionization, an avalanche breakdown, a short-channel effect, or the like does not occur. Thus, the use of an OS transistor enables formation of a circuit having high withstand voltage and high reliability. Moreover, variation in electrical characteristics due to crystallinity unevenness, which is caused in Si transistors, is less likely to occur in OS transistors.

A semiconductor layer included in the OS transistor can be, for example, a film represented by an In-M-Zn-based oxide that contains indium, zinc, and M (M is one or more of metals such as aluminum, titanium, gallium, germanium, yttrium, zirconium, lanthanum, cerium, tin, neodymium, and hafnium). The In-M-Zn-based oxide can be typically formed by a sputtering method. Alternatively, the In-M-Zn-based oxide can be formed by an ALD (Atomic layer deposition) method.

It is preferable that the atomic ratio of metal elements in a sputtering target used to form the In-M-Zn-based oxide by a sputtering method satisfy In M and Zn M. The atomic ratio of metal elements of such a sputtering target is preferably In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, In:M:Zn=5:1:8, or the like. Note that the atomic ratio in the deposited semiconductor layer varies from the atomic ratio of metal elements contained in the sputtering target in a range of ±40%.

An oxide semiconductor with a low carrier density is used for the semiconductor layer. For example, for the semiconductor layer, an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. The oxide semiconductor has a low density of defect states and can thus be regarded as an oxide semiconductor having stable characteristics. Note that the composition is not limited to those described above, and an oxide semiconductor having an appropriate composition can be used depending on required semiconductor characteristics and electrical characteristics (e.g., field-effect mobility and threshold voltage) of the transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

When silicon or carbon, which is one of the Group 14 elements, is contained in the oxide semiconductor that included in the semiconductor layer, oxygen vacancies are increased, and the semiconductor layer becomes n-type. Thus, the concentration (concentration obtained by secondary ion mass spectrometry) of silicon or carbon in the semiconductor layer is set lower than or equal to 2×10¹⁸ atoms/cm³, preferably lower than or equal to 2×10¹⁷ atoms/cm³.

Alkali metal and alkaline earth metal might generate carriers when bonded to an oxide semiconductor, in which case the off-state current of the transistor might be increased. Thus, the concentration of alkali metal or alkaline earth metal in the semiconductor layer (the concentration obtained by secondary ion mass spectrometry) is set to 1×10¹⁸ atoms/cm³ or lower, preferably 2 5×10¹⁶ atoms/cm³ or lower.

When nitrogen is contained in the oxide semiconductor included in the semiconductor layer, electrons serving as carriers are generated and the carrier density increases, so that the semiconductor layer easily becomes n-type. As a result, a transistor using an oxide semiconductor that contains nitrogen is likely to have normally-on characteristics. Therefore, the concentration (concentration obtained by secondary ion mass spectrometry) of nitrogen in the semiconductor layer is preferably set to 5×10¹⁸ atoms/cm³ or lower.

When hydrogen is contained in the oxide semiconductor included in the semiconductor layer, hydrogen reacts with oxygen bonded to a metal atom to be water, and thus sometimes causes an oxygen vacancy in the oxide semiconductor. When the channel formation region in the oxide semiconductor includes oxygen vacancies, the transistor sometimes has normally-on characteristics. In some cases, a defect in which hydrogen has entered an oxygen vacancy functions as a donor and generates an electron serving as a carrier. In other cases, bonding of part of hydrogen to oxygen bonded to a metal atom generates an electron serving as a carrier. Thus, a transistor using an oxide semiconductor that contains a large amount of hydrogen is likely to have normally-on characteristics.

A defect in which hydrogen has entered an oxygen vacancy can function as a donor of the oxide semiconductor. However, it is difficult to evaluate the defect quantitatively. For this reason, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” in this specification and the like can be replaced with “donor concentration” in some cases.

Therefore, hydrogen in the oxide semiconductor is preferably reduced as much as possible. Specifically, the hydrogen concentration in the oxide semiconductor, which is measured by secondary ion mass spectrometry (SIMS), is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When an oxide semiconductor with sufficiently reduced impurities such as hydrogen is used for a channel formation region of a transistor, the transistor can have stable electrical characteristics.

The manufacturing equipment of a display device of one embodiment of the present invention includes a sputtering apparatus or an ALD apparatus and is capable of forming a high-quality oxide semiconductor.

FIG. 13A illustrates the structure in which the light-emitting layers in the R, G, and B light-emitting elements are different from each other as an example; however, one embodiment of the present invention is not limited thereto. For example, as illustrated in FIG. 13B, a coloring method may be employed in which the light-emitting elements 110R, 110G, and 110B are formed by providing EL layers 112W that emit white light and providing coloring layers 114R (red), 114G (green), and 114B (blue) that overlap with the EL layers 112W.

The EL layer 112W can have a tandem structure in which EL layers emitting R, G, and B light are connected in series, for example. Alternatively, a structure in which light-emitting layers emitting R, G, and B light are connected in series may be used. As the coloring layers 114R, 114G, and 114B, for example, red, green, and blue color filters can be used.

As illustrated in FIG. 13C, a pixel circuit may be formed with a transistor 117 included in the substrate 60, and one of a source and a drain of the transistor 117 may be electrically connected to the pixel electrode 111.

Here, the transistor 117 is a Si transistor formed in the substrate 60. In the manufacturing equipment of one embodiment of the present invention, the substrate 60 in which the transistor 117 is formed is loaded from the load chamber provided for the transfer chamber TF4, light-emitting elements are formed in the cluster 20E and the cluster 30E, and the substrate 60 is carried out from the unload chamber provided for the transfer chamber TF4. Meanwhile, different treatment (e.g., formation of an OS transistor) can be performed in the cluster 20 and the cluster 30, for example.

<Example of Manufacturing Method>

A manufacturing method of a display device of one embodiment of the present invention will be described below. The description will be made here using a display device included in the display device 100 described in the above structure example as an example.

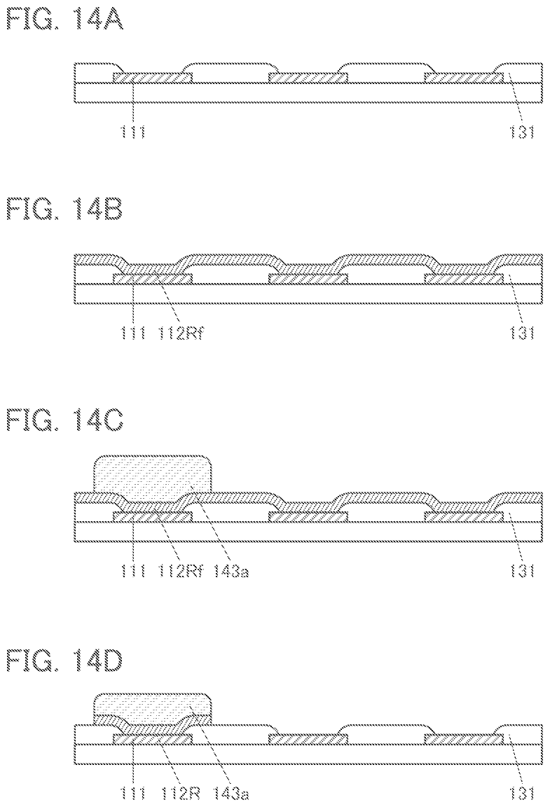

FIG. 14A to FIG. 16D are schematic cross-sectional views of steps in the manufacturing method of a display device described below as an example. The transistor 116 that is a component of the pixel circuit and the transistor 115 that is a component of the driver circuit, which are illustrated in FIG. 13A, are omitted in FIG. 14A to FIG. 16D.

Thin films (e.g., an insulating film, a semiconductor film, and a conductive film) included in the display device can be formed by a sputtering method, a chemical vapor deposition (CVD) method, a vacuum evaporation method, an atomic layer deposition (ALD) method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method. The manufacturing equipment of one embodiment of the present invention can include an apparatus for forming thin films by the above method.

A method such as spin coating, dipping, spray coating, ink-jetting, dispensing, screen printing, offset printing, a doctor knife method, slit coating, roll coating, curtain coating, or knife coating can be employed for formation of the thin films constituting the display device (e.g., insulating films, semiconductor films, and conductive films) and application of a resin used for a lithography step or the like. The manufacturing equipment of one embodiment of the present invention can include an apparatus for forming thin films by the above method. In addition, the manufacturing equipment of one embodiment of the present invention can include an apparatus for applying a resin by the above method.

When the thin films included in the display device are processed, a photolithography method or the like can be used. Alternatively, the thin films may be processed by a nanoimprinting method. A method in which island-shaped thin films are directly formed by a film formation method using a shielding mask may also be used.

There are two typical methods as a thin film processing method using a photolithography method. In one of the methods, a resist mask is formed over a thin film to be processed, the thin film is processed by etching or the like, and then the resist mask is removed. In the other method, a photosensitive thin film is formed and then processed into a desired shape by light exposure and development.

As the light used for exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Exposure may be performed by liquid immersion exposure technique. As the light used for the exposure, extreme ultraviolet (EUV) light or X-rays may be used. Instead of the light used for the exposure, an electron beam can also be used. Extreme ultraviolet light, X-rays, or an electron beam is preferably used, in which case extremely minute processing can be performed. Note that in the case of performing exposure by scanning of a beam such as an electron beam, a photomask is not needed.

For etching of the thin film, a dry etching method, a wet etching method, or the like can be used. The manufacturing equipment of one embodiment of the present invention can include an apparatus for processing thin films by the above method.

<Preparation of Substrate 60>

A substrate that has heat resistance high enough to withstand at least heat treatment performed later can be used as the substrate 60. In the case where an insulating substrate is used as the substrate 60, a glass substrate, a quartz substrate, a sapphire substrate, a ceramic substrate, an organic resin substrate, or the like can be used. Alternatively, a semiconductor substrate such as a single crystal semiconductor substrate or a polycrystalline semiconductor substrate including silicon, silicon carbide, or the like as a material, a compound semiconductor substrate of silicon germanium or the like, or an SOI substrate can be used.

As the substrate 60, it is particularly preferable to use the semiconductor substrate or the insulating substrate over which a semiconductor circuit including a semiconductor element such as a transistor is formed. The semiconductor circuit preferably forms, for example, a pixel circuit, a gate line driver circuit (a gate driver), and a source line driver circuit (a source driver). In addition to the above, an arithmetic circuit, a memory circuit, or the like may be formed.

<Formation of Pixel Circuit and Pixel Electrode 111>

Next, a plurality of pixel circuits are formed over the substrate 60, and a pixel electrode 111 is formed for each of the pixel circuits. First, a conductive film to be the pixel electrodes 111 is formed, a resist mask is formed by a photolithography method, and an unnecessary portion of the conductive film is removed by etching. After that, the resist mask is removed, so that the pixel electrodes 111 can be formed.

It is preferable to use, for the pixel electrodes 111, a material (e.g., silver or aluminum) having reflectance as high as possible in the whole wavelength range of visible light. The pixel electrodes 111 formed using the material can be referred to as light-reflecting electrodes. In that case, it is possible to increase not only light extraction efficiency but also color reproducibility of the light-emitting elements.

<Formation of Insulating Layer 131>

Subsequently, the insulating layer 131 is formed to cover end portions of the pixel electrodes 111 (see FIG. 14A). An organic insulating film or an inorganic insulating film can be used as the insulating layer 131. End portions of the insulating layer 131 are preferably tapered to improve step coverage with an EL film to be formed later. In particular, when an organic insulating film is used, a photosensitive material is preferably used, in which case the shape of the end portions can be easily controlled by the conditions of light exposure and development.

<Formation of EL Film 112Rf>

Next, an EL film 112Rf to be an EL layer 112R later is formed over the pixel electrodes 111 and the insulating layer 131 (see FIG. 14B).

The EL film 112Rf includes at least a film containing a red-light-emitting organic compound. A structure may be employed in which an electron-injection layer, an electron-transport layer, a charge-generation layer, a hole-transport layer, and a hole-injection layer are stacked in addition to the above. The EL film 112Rf can be formed by an evaporation method or a sputtering method, for example. Without limitation to this, the above-described film formation method can be used as appropriate.

<Formation of Resist Mask 143a>

Next, a resist mask 143a is formed over the pixel electrode 111 corresponding to the light-emitting element 110R (see FIG. 14C). The resist mask 143a can be formed by a lithography step.

<Formation of EL Layer 112R>

Then, the EL film 112Rf is etched using the resist mask 143a as a mask, so that the EL layer 112R is formed to have an island shape (see FIG. 14D). A dry etching method or a wet etching method can be used for the etching step.

<Formation of EL Film 112Gf>

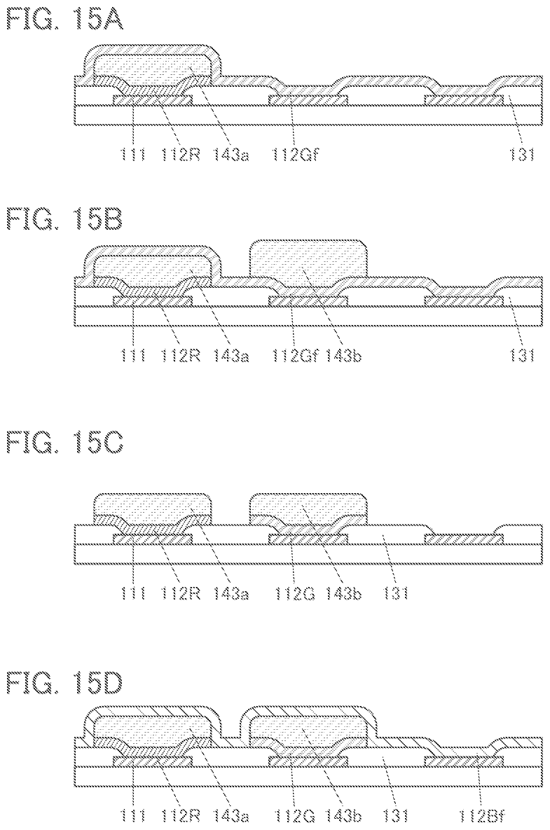

Subsequently, an EL film 112Gf to be the EL layer 112G later is formed over the pixel electrodes 111 and the insulating layer 131 that are exposed and the resist mask 143a (see FIG. 15A).

The EL film 112Gf includes at least a film containing a green-light-emitting organic compound. A structure may be employed in which an electron-injection layer, an electron-transport layer, a charge-generation layer, a hole-transport layer, and a hole-injection layer are stacked in addition to the above.

<Formation of Resist Mask 143b>

Next, a resist mask 143b is formed over the pixel electrode 111 corresponding to the light-emitting element 110G (see FIG. 15B). The resist mask 143b can be formed by a lithography step.

<Formation of EL Layer 112G>

Then, the EL film 11Gf is etched using the resist mask 143b as a mask, so that the EL layer 112G is formed to have an island shape (see FIG. 15C). A dry etching method or a wet etching method can be used for the etching step.

<Formation of EL Film 112Bf>

Subsequently, an EL film 112Bf to be an EL layer 112B later is formed over the pixel electrode 111 and the insulating layer 131 that are exposed, the resist mask 143a, and the resist mask 143b (see FIG. 15D).

The EL film 112Bf includes at least a film containing a blue-light-emitting compound. A structure may be employed in which an electron-injection layer, an electron-transport layer, a charge-generation layer, a hole-transport layer, and a hole-injection layer are stacked in addition to the above.

<Formation of Resist Mask 143c>

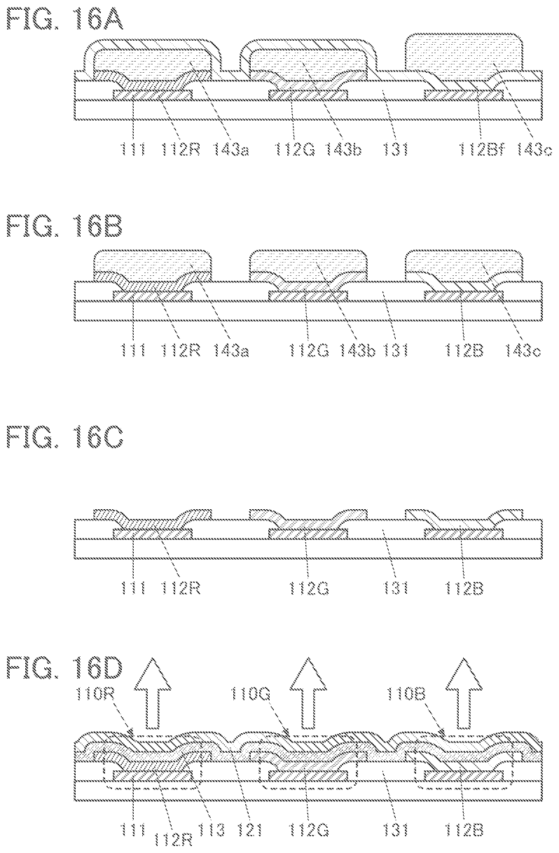

Next, a resist mask 143c is formed over the pixel electrode 111 corresponding to the light-emitting element 110B (see FIG. 16A). The resist mask 143b can be formed by a lithography step.

<Formation of EL Layer 112B>

Then, the EL film 112Bf is etched using the resist mask 143c as a mask, so that the EL layer 112G is formed to have an island shape (see FIG. 16B). A dry etching method or a wet etching method can be used for the etching step.

<Removal of Resist Mask>

Subsequently, the resist mask 143a, the resist mask 143b, and the resist mask 143c are removed (see FIG. 16C). To removal the resist masks, a stripping method using an organic solvent can be used, for example. Alternatively, ashing with a dry etching apparatus may be used, for example.

<Formation of Common Electrode>

Then, a conductive film to be the common electrode 113 of the organic EL elements is formed over the EL layer 112R, the EL layer 112G, and the EL layer 112B that are exposed in the previous step and the insulating layer 131. As the common electrode 113, either one of a thin metal film that transmits light emitted from the light-emitting layer (e.g., an alloy of silver and magnesium) and a light-transmitting conductive film (e.g., indium tin oxide or an oxide containing one or more of indium, gallium, zinc, and the like) or a stack of these films can be used. The common electrode 113 formed using such a film can be referred to as a light-transmitting electrode. For the step of forming the conductive film to be the common electrode 113, an evaporation apparatus and/or a sputtering apparatus can be used, for example.

The light-reflecting electrodes are included as the pixel electrodes 111 and the light-transmitting electrode is included as the common electrode 113, whereby light emitted from the light-emitting layers can be emitted to the outside through the common electrode 113. In other words, top-emission light-emitting elements are formed.

<Formation of Protective Layer>

Next, the protective layer 121 is formed over the common electrode 113 (see FIG. 16D). A sputtering apparatus, a CVD apparatus, an ALD apparatus, or the like can be used for the step of forming the protective layer.

### Example 1 of Manufacturing Equipment

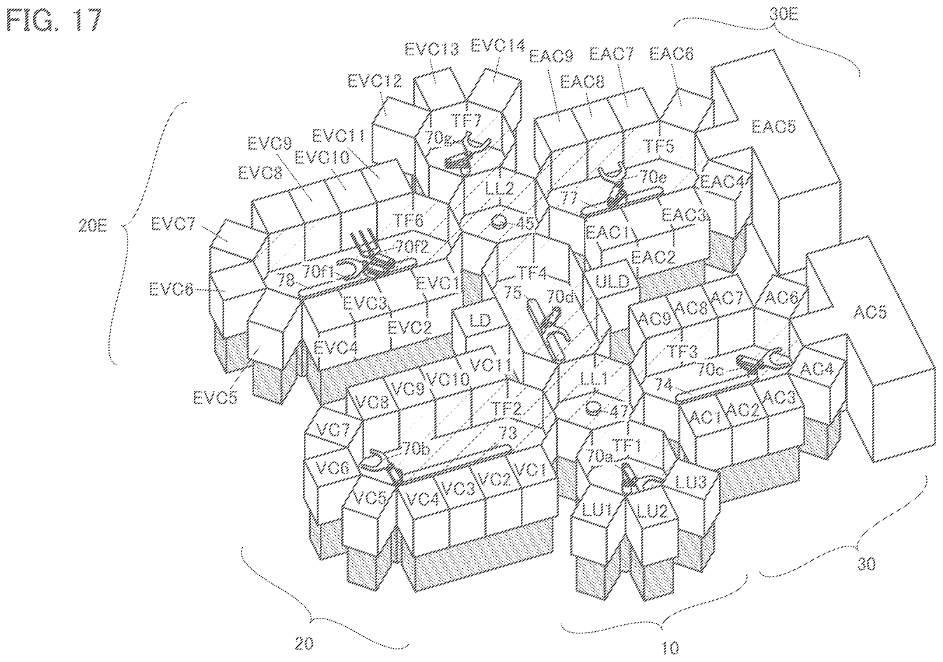

FIG. 17 illustrates an example of manufacturing equipment that can be used for the above-described steps from the formation of the pixel circuits and the EL film 112Rf up to the formation of the protective layer 121. In FIG. 17 illustrating the example of the manufacturing equipment, whose basic structure is the same as that of the manufacturing equipment illustrated in FIG. 1, necessary apparatuses are specifically illustrated in consideration of formation steps of transistors, formation of R, G, and B light-emitting elements, process time shortened by multitasking, and the like.

The cluster 20E, the cluster 30E, the cluster 20, and the cluster 30 will be specifically described below. FIG. 17 is a schematic perspective view of the whole of the manufacturing equipment, where utility equipment, gate valves, and the like are not illustrated. Moreover, in FIG. 17, the insides of the transfer chambers TF1 to TF7 and the load lock chambers LL1 and LL2 are made visible for clarity.

<Cluster 20E>

The cluster 20E includes a block that includes the transfer chamber TF5, the vacuum process apparatuses EVC1 to EVC11 and a block that includes the transfer chamber TF7 and vacuum process apparatuses EVC12 to EVC14. Note that the transfer chamber TF6 and the vacuum process apparatuses EVC1 to EVC14 may be formed as one block without dividing the cluster 20E into two blocks.

The transfer chamber TF6 includes the delivery devices 70f1 and 70f2. The transfer chamber TF7 includes a delivery device 70g. Here, the delivery devices 70f1 and 70f2 are self-propelled and can move along a rail 78.

<EVC1 to EVC5>

The vacuum process apparatuses EVC1 to EVC5 are evaporation apparatuses for formation of the EL film 112Rf, the EL film 112Gf, and the EL film 112Bf. For example, the vacuum process apparatuses EVC2, EVC3, and EVC4 can be formation apparatuses for a light-emitting layer (R), a light-emitting layer (G), and a light-emitting layer (B), respectively. The vacuum process apparatuses EVC1 and EVC5 can be designated as apparatuses for formation of common layers such as an electron-injection layer, an electron-transport layer, a charge-generation layer, a hole-transport layer, and a hole-injection layer.

<EVC6 and EVC7>

The vacuum process apparatus EVC6 can be a device detaching the substrate delivery jig described with reference to FIG. 2A and FIG. 2B. The delivery device 70f1 can carry a substrate into the vacuum process apparatus EVC6 and attach the substrate delivery jig to the substrate. In addition, the substrate delivery jig can be detached in the vacuum process apparatus EVC6 and the substrate alone can be carried out.

The vacuum process apparatus EVC7 can be the substrate reversing device described with reference to FIG. 5A and FIG. 5B. The vacuum process apparatus EVC7 can reverse the work substrate 50 as needed.

<EVC8 and EVC9>

The vacuum process apparatuses EVC8 and EVC9 can be film formation apparatuses for formation of the common electrode 113. For example, the vacuum process apparatus EVC8 can be an evaporation apparatus used for formation of a metal film transmitting visible light. The vacuum process apparatus EVC9 can be a sputtering apparatus used for formation of a light-transmitting conductive film.

<EVC10 and EVC11>

The vacuum process apparatus EVC10 can be a film formation apparatus for formation of the protective layer 121. For example, the vacuum process apparatus EVC10 can be a sputtering apparatus. Alternatively, the vacuum process apparatus EVC10 may be a CVD apparatus, an ALD apparatus, or the like. Further alternatively, another vacuum process apparatus EVC may be provided and a plurality of different film formation apparatuses may be provided to form the protective layer 121 as a stacked-layer film.

The vacuum process apparatus EVC11 can be a dry etching apparatus for formation of the EL layer 112R, the EL layer 112G, and the EL layer 112B and removal of resist masks. Alternatively, another vacuum process apparatus EVC may be provided and another ashing apparatus may be provided.

<EVC12 to EVC14>

One or more of the vacuum process apparatuses EVC12, EVC13, and EVC14 can be vacuum baking apparatuses. The reliability of an organic EL element is impaired by the entry of impurities such as water; for this reason, it is preferable that vacuum baking (heat treatment under reduced pressure) be performed in a step preceding formation of the EL film 112Rf, the EL film 112Gf, and the EL film 112Bf to remove impurities such as water attached onto the work substrate 50.

Although the number of each kind of provided apparatus is one in the above-described example, two or three apparatuses that require a relatively long process time may be provided. For example, all of the vacuum process apparatuses EVC12, EVC13, and EVC14 can be vacuum baking apparatuses.

<Cluster 30E>

The cluster 30E includes the transfer chamber TF5 and the normal-pressure process apparatuses EAC1 to EAC9.

The transfer chamber TF5 includes the delivery device 70e. The delivery device 70e is self-propelled and can move along a rail 77.

<EAC1 to EAC3>

As the normal-pressure process apparatuses EAC1 to EAC3, any one or more of a cleaning apparatus, a wet etching apparatus, a resist stripping apparatus, a counter substrate bonding apparatus, and the like can be designated. The apparatuses can be selected as appropriate depending on the steps.

<EAC4 to EAC9>

The normal-pressure process apparatuses EAC4 to EAC9 can be apparatuses used for a lithography step. For example, the normal-pressure process apparatus EAC4 can be a resin (photoresist) application apparatus, the normal-pressure process apparatus EAC5 can be a light-exposure apparatus, and the normal-pressure process apparatus EAC6 can be a development apparatus.

Alternatively, the normal-pressure process apparatus EAC4 can be a resin (e.g., UV-curable resin) application apparatus, the normal-pressure process apparatus EAC5 can be a nanoimprint apparatus, and the normal-pressure process apparatus EAC6 can be a development apparatus. In the case where a development apparatus is not used, a different apparatus may be designated as the normal-pressure process apparatus EAC6.

The normal-pressure process apparatuses EAC7 to EAC9 can be baking apparatuses. The baking apparatus is capable of performing pre-baking or post-baking of a photoresist, drying after cleaning, or the like.

<Cluster 20>

The cluster 20 includes a block that includes the transfer chamber TF2 and the vacuum process apparatuses VC1 to VC11.

The transfer chamber TF2 includes the delivery device 70b. Here, the delivery device 70b is self-propelled and can move along a rail 73.

<VC1 to VC3>

The vacuum process apparatuses VC1 to VC3 can be sputtering apparatuses for formation of an insulating layer, a semiconductor layer (e.g., a metal oxide), a conductive layer, and the like. For example, the vacuum process apparatuses VC1, VC2, and VC3 can be dedicated apparatuses for formation of an insulating layer, a semiconductor layer, and a conductive layer, respectively.

<VC4 to VC6>

The vacuum process apparatuses VC4 to VC6 can be dry etching apparatuses for patterning of layers after lithography, formation of contact holes, and removal (ashing) of resist masks. Alternatively, another vacuum process apparatus VC may be provided as an ashing apparatus.

<VC7 to VC9>

The vacuum process apparatuses VC7 to VC9 are CVD apparatuses for formation of an insulating layer, a conductive layer, and the like. For example, a plasma CVD apparatus can be used to form an insulating film and thermal CVD using a source gas containing a metal, or the like can be used to form a conductive layer (metal).

<VC10 and VC11>

The vacuum process apparatus VC10 can be an ALD apparatus. The ALD apparatus has excellent step coverage and can thus be used for a protective layer, a gate insulating layer, and the like. The vacuum process apparatus VC11 can be a plasma treatment apparatus. The plasma treatment apparatus enables oxygen to be supplied to a gate insulating layer, so that the gate insulating layer can have high quality. Moreover, in the case of using an OS transistor, oxygen can be supplied to a channel formation region through the gate insulating layer.

<Cluster 30>

The cluster 30 includes the transfer chamber TF3 and the normal-pressure process apparatuses AC1 to AC9.

The transfer chamber TF3 includes the delivery device 70e. The delivery device 70e is self-propelled and can move along a rail 74.

<AC1 and AC2>

As the normal-pressure process apparatuses AC1 and AC2, any one or more of a cleaning apparatus, a wet etching apparatus, a CMP apparatus, a resist stripping apparatus, and the like can be designated. The apparatuses can be selected as appropriate depending on the steps. Any of the above apparatuses may be designated as another normal-pressure process apparatus AC.

<AC4 to AC9>

The normal-pressure process apparatuses AC4 to AC6 can be apparatuses used for a lithography step. The normal-pressure process apparatuses AC4 to AC6 can have the same structure as the normal-pressure process apparatuses EAC4 to EAC6.

The normal-pressure process apparatuses AC7 to AC9 can be baking apparatuses. The baking apparatus is capable of performing pre-baking or post-baking of a photoresist, drying after cleaning, or the like.

### Example 2 of Manufacturing Equipment

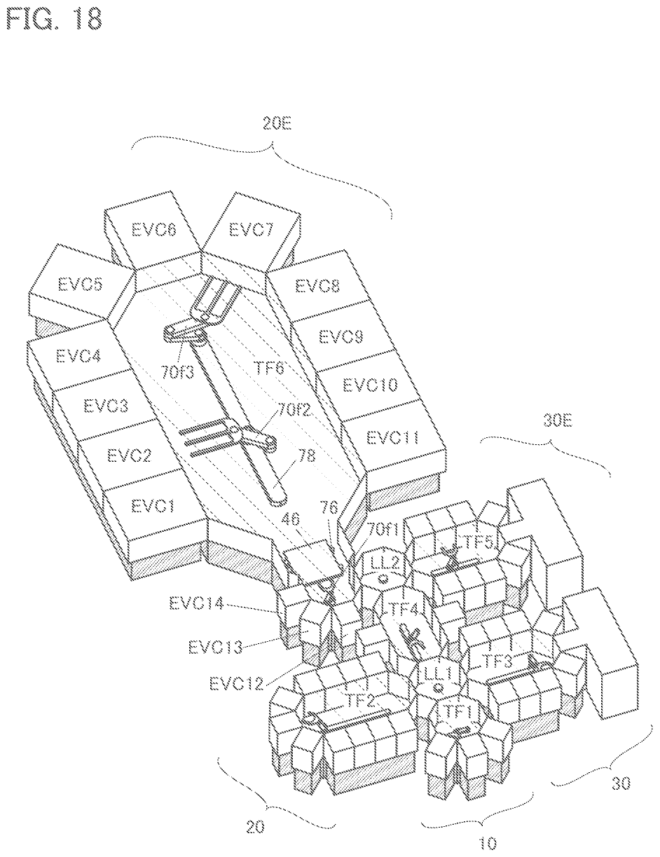

FIG. 18 illustrates an example in which necessary apparatuses are specifically illustrated as in FIG. 17, using the manufacturing equipment illustrated in FIG. 9 as a basis structure. The load/unload unit 10, the cluster 20, the cluster 30, and the cluster 30E can have the same structure as those in FIG. 17 and are different from those in FIG. 17 in that the structure of the cluster 20E is increased in size and that the transfer chamber TF7 is combined with the transfer chamber TF6.

In the structure of the cluster 20, components for performing batch processing of the substrates 60 described with reference to FIG. 9 to FIG. 11 are provided and the delivery device 70f2 is increased in size. Although a delivery device 70f3 that is similar to the delivery device 70f2 is provided, the delivery device 70f3 is not necessarily provided.

The vacuum process apparatuses EVC12 to EVC14, which are vacuum baking apparatuses, are not necessarily compatible with to large size. A vacuum baking step is performed before a delivery jig is attached to the substrate 60 and is thus capable of performing treatment for each substrate 60.

Table 1 and Table 2 each summarize the steps using the cluster 20E and the cluster 30E in the manufacturing equipment illustrated in FIG. 17, treatment apparatuses, the orientation of the substrate (up: face-up mode, down: face-down mode), and components corresponding to the above-described manufacturing method. Note that the tables omit carrying in and out the substrate to and from the load lock chamber LL2 and the apparatuses.

Table 1 shows the steps following the formation of the pixel electrodes 111 up to the formation of one kind of EL layer. These steps are performed for each of the R, G, and B EL layers; accordingly, the steps from No. 1 to No. 16 in Table 1 are performed three times.

TABLE 1

| | | | Orien- | |
|---|---|---|---|---|
| | | | tation | |
| Step | | Treatment | of sub- | Corresponding |
| No. | Step | apparatus | strate | component |
| 1 | Cleaning | AC1 | up | |
| 2 | Vacuum baking | VC12 | up | |
| 3 | Attaching delivery jig | VC6 | up | |
| 4 | Reversing substrate | VC7 | down | |
| 5 | Forming common layer | VC1 | down | EL film 112Rf, |
| 6 | Forming light-emitting layer | VC2, | down | 112Gf, 112Bf |
| | | VC3, | | |
| | | VC4 | | |
| 7 | Forming common layer | VC5 | down | |
| 8 | Reversing substrate | VC7 | up | |
| 9 | Detaching delivery jig | VC6 | up | |
| 10 | Applying photoresist | AC4 | up | Resist mask |
| 11 | Pre-baking | AC7 | up | 143a, 143b, |
| 12 | Light exposure | AC5 | up | 143c |
| 13 | Development | AC6 | up | |
| 14 | Post-baking | AC8 | up | |
| 15 | Etching EL film | VC11 | up | EL layer 112R, |
| 16 | Removing resist mask | AC3 | up | 112G, 112B |

Table 2 shows the steps following the formation of the EL layers 112R, 112G, and 112B up to the formation of the protective layer 121. In replacement of the substrate delivery jig in Step No. 55, the jig 54 attached in Step No. 50 is replaced with the jig 54 having a larger opening than the jig 54 attached in Step No. 50. Accordingly, the protective layer covering an end portion of the common electrode can be provided.

TABLE 2

| | | | Orien- | |
|---|---|---|---|---|
| | | | tation | |
| Step | | Treatment | of sub- | Corresponding |
| No. | Step | apparatus | strate | component |
| 49 | Vacuum baking | VC12 | up | |
| 50 | Attaching delivery jig | VC6 | up | |
| 51 | Reversing substrate | VC7 | down | |
| 52 | Forming common electrode | VC8 | down | Common |
| 53 | Forming common electrode | VC9 | down | electrode 113 |
| 54 | Reversing substrate | VC7 | up | |
| 55 | Replacing delivery jig | VC6 | up | |
| 59 | Reversing substrate | VC7 | down | |
| 57 | Forming protective layer | VC10 | down | Protective |
| | | | | layer 121 |
| 58 | Reversing substrate | VC7 | up | |
| 59 | Detaching delivery jig | VC6 | up | |

The manufacturing equipment of one embodiment of the present invention has a function of performing Step No. 1 in Table 1 to Step No. 59 in Table 2 automatically.

This embodiment can be implemented in an appropriate combination with the structures described in the other embodiment.

### REFERENCE NUMERALS

AC1: normal-pressure process apparatus, AC2: normal-pressure process apparatus, AC3: normal-pressure process apparatus, AC4: normal-pressure process apparatus, AC5: normal-pressure process apparatus, AC6: normal-pressure process apparatus, AC7: normal-pressure process apparatus, AC8: normal-pressure process apparatus, AC9: normal-pressure process apparatus, EAC1: normal-pressure process apparatus, EAC2: normal-pressure process apparatus, EAC3: normal-pressure process apparatus, EAC4: normal-pressure process apparatus, EAC5: normal-pressure process apparatus, EAC6: normal-pressure process apparatus, EAC7: normal-pressure process apparatus, EAC8: normal-pressure process apparatus, EAC9: normal-pressure process apparatus, EVC1: vacuum process apparatus, EVC2: vacuum process apparatus, EVC3: vacuum process apparatus, EVC4: vacuum process apparatus, EVC5: vacuum process apparatus, EVC6: vacuum process apparatus, EVC7: vacuum process apparatus, EVC8: vacuum process apparatus, EVC9: vacuum process apparatus, EVC10: vacuum process apparatus, EVC11: vacuum process apparatus, EVC12: vacuum process apparatus, EVC13: vacuum process apparatus, EVC14: vacuum process apparatus, LL1: load lock chamber, LL2: load lock chamber, LU1: load/unload chamber, TF1: transfer chamber, TF2: transfer chamber, TF3: transfer chamber, TF4: transfer chamber, TF5: transfer chamber, TF6: transfer chamber, TF7: transfer chamber, VC1: vacuum process apparatus, VC2: vacuum process apparatus, VC3: vacuum process apparatus, VC4: vacuum process apparatus, VC5: vacuum process apparatus, VC6: vacuum process apparatus, VC7: vacuum process apparatus, VC8: vacuum process apparatus, VC9: vacuum process apparatus, VC10: vacuum process apparatus, VC11: vacuum process apparatus, 10: load/unload unit, 20: cluster, 20E: cluster, 30: cluster, 30E: cluster, 45: substrate rotation mechanism, 46: stage, 47: substrate rotation mechanism, 50: work substrate, 51: jig, 52: through hole, 53: through hole, 54: jig, 55: magnet, 56: projection, 57: shape portion, 58: through hole, 59: depression portion, 60: substrate, 61: notch, 62: pin, 65: camera, 66: delivery device, 69: pusher pin, 70: delivery device, 70a: delivery device, 70b: delivery device, 70c: delivery device, 70d: delivery device, 70e: delivery device, 70f1: delivery device, 70f2: delivery device, 70f3: delivery device, 70g: delivery device, 71: hand portion, 73: rail, 74: rail, 75: rail, 76: rail, 77: rail, 78: rail, 80: substrate reversing device, 81: support, 82: pillar, 83: rotation mechanism, 84: rotation portion, 85a: hand portion, 85b: hand portion, 86a: horizontal movement mechanism, 86b: horizontal movement mechanism, 87: shape portion, 90a: evaporation apparatus, 90b: dry etching apparatus, 91: rail, 92: evaporation source, 95: cathode, 96: anode, 100: display device, 110B: light-emitting element, 110G: light-emitting element, 110R: light-emitting element, 111: pixel electrode, 112B: EL layer, 112Bf: EL film, 112G: EL layer, 112Gf: EL film, 112R: EL layer, 112Rf: EL film, 112W: EL layer, 113: common electrode, 114B: coloring layer, 114G: coloring layer, 114R: coloring layer, 115: transistor, 116: transistor, 117: transistor, 121: protective layer, 131: insulating layer, 143a: resist mask, 143b: resist mask, 143c: resist mask

1. A manufacturing equipment of a display device, comprising a manufacturing apparatus of a pixel circuit and a manufacturing apparatus of a light-emitting device,
wherein the manufacturing apparatus of the light-emitting device comprises a first load lock chamber, a first cluster, and a second cluster,
wherein the first load lock chamber is connected to the first cluster through a first gate valve,
wherein the first load lock chamber is connected to the second cluster through a second gate valve,
wherein pressure in the first load lock chamber is controlled to be reduced pressure or an atmosphere therein is controlled to be an inert gas atmosphere,
wherein pressure in the first cluster is controlled to be reduced pressure,
wherein an atmosphere in the second cluster is controlled to be an inert gas atmosphere,
wherein the first cluster comprises a first delivery device, a plurality of film formation apparatuses, and an etching apparatus,
wherein the second cluster comprises a second delivery device and a plurality of apparatuses performing a lithography step,
wherein the manufacturing apparatus of the pixel circuit comprises a second load lock chamber,
wherein the first load lock chamber is connected to the second load lock chamber through a transfer chamber, and
wherein the manufacturing equipment is configured to form the light-emitting device comprising an organic compound over a pixel electrode formed over a substrate in the manufacturing apparatus of the pixel circuit.

2. The manufacturing equipment of the display device, according to claim 1,
wherein the film formation apparatus is one or more selected from an evaporation apparatus, a sputtering apparatus, a CVD apparatus, and an ALD apparatus, and
wherein the etching apparatus is a dry etching apparatus.

3. The manufacturing equipment of the display device, according to claim 1,
wherein the first cluster comprises a vacuum baking apparatus.

4. The manufacturing equipment of the display device, according to claim 1,
wherein the plurality of apparatuses performing the lithography step comprise an application apparatus, a light-exposure apparatus, a development apparatus, and a baking apparatus.

5. The manufacturing equipment of the display device, according to claim 1,
wherein the plurality of apparatuses performing the lithography step comprise an application apparatus and a nanoimprint apparatus.

6. The manufacturing equipment of the display device, according to claim 1,
wherein the etching apparatus is configured to process the organic compound into an island shape.

7. The manufacturing equipment of the display device, according to claim 1,
wherein in the first cluster, the substrate attached to a substrate delivery jig is subjected to treatment.

8. The manufacturing equipment of the display device, according to claim 7,
wherein the substrate delivery jig comprises a first jig and a second jig, and
wherein the substrate is held between the first jig and the second jig.

9. The manufacturing equipment of the display device, according to claim 7,
wherein the substrate delivery jig comprises a first jig and a plurality of second jigs,
wherein a plurality of the substrates are placed apart from each other over the first jig, and
wherein the substrates are held between the first jig and the second jigs.

10. The manufacturing equipment of the display device, according to claim 7,
wherein the first cluster comprises a device detaching the substrate delivery jig.

11. The manufacturing equipment of the display device, according to claim 7,
wherein the first cluster comprises a device reversing the substrate to which the substrate delivery jig is attached.

12. The manufacturing equipment of the display device, according to claim 1,
wherein the manufacturing apparatus of the pixel circuit comprises a third cluster and a fourth cluster,
wherein the second load lock chamber is connected to the third cluster through a third gate valve,
wherein the second load lock chamber is connected to the fourth cluster through a fourth gate valve,
wherein pressure in the second load lock chamber is controlled to be reduced pressure or normal pressure,
wherein pressure in the third cluster is controlled to be reduced pressure,
wherein pressure in the fourth cluster is controlled to be normal pressure,
wherein the third cluster comprises a third delivery device, a plurality of film formation apparatuses, an etching apparatus, and a plasma treatment apparatus, and
wherein the second cluster comprises a fourth delivery device, a plurality of apparatuses performing a lithography step, and a polishing apparatus.

13. The manufacturing equipment of the display device, according to claim 12,
wherein the plurality of film formation apparatuses are one or more selected from a sputtering apparatus, a CVD apparatus, and an ALD apparatus,
wherein the etching apparatus is a dry etching apparatus, and
wherein the polishing apparatus is a CMP apparatus.

14. The manufacturing equipment of the display device, according to claim 12,
wherein the plurality of apparatuses performing the lithography step comprise an application apparatus, a light-exposure apparatus, a development apparatus, and a baking apparatus.

15. The manufacturing equipment of the display device, according to claim 12,
wherein the first load lock chamber is connected to the second load lock chamber through a fifth gate valve and the transfer chamber.

16. The manufacturing equipment of the display device, according to claim 1,
wherein the substrate is a silicon wafer.

17. The manufacturing equipment of the display device, according to claim 16,
wherein the silicon wafer is provided with a driver circuit, and
wherein the manufacturing equipment forms the pixel circuit electrically connected to the driver circuit.
